(19) United States
(12) Patent Application Publication
(10) Pub. No.: US 2026/0369518 A1
(43) Pub. Date: Nov. 19, 2026

(54) MAGNETIC ELECTRON TRAP

(71) Applicant: Oxford Instruments Nanotechnology Tools Limited, High Wycombe (GB)

(72) Inventors: Thomas Altebaeumer, High Wycombe (GB); Logan Forth, High Wycombe (GB); Santokh Bhadare, High Wycombe (GB); Chris Tyrrell, High Wycombe (GB); Grace Munday, High Wycombe (GB)

(73) Assignee: Oxford Instruments Nanotechnology Tools Limited, High Wycombe (GB)

(21) Appl. No.: 19/653,775

(22) Filed: Apr. 21, 2026

(30) Foreign Application Priority Data
Apr. 22, 2025 (GB) 2505992.4

(51) Int. Cl. H01J 37/244

(52) U.S. Cl. CPC H01J 37/244; H01J 2237/028; H01J 2237/24415; H01J 2237/2448

(57) ABSTRACT

An electron trap for use in a system for performing x-ray analysis of a specimen in provided. The electron trap includes a magnet arrangement including a first set of two opposing magnetic elements and a second set of two opposing magnetic elements, the magnetic elements arranged so as to define an interior region therebetween such that when in use, electrons travelling from the specimen and received by the electron trap enter the interior region through an entrance plane at a receiving end of the electron trap, the entrance plane being perpendicular to a longitudinal axis of the magnet arrangement; wherein an extent of a projection of the magnet arrangement onto the entrance plane in a height direction is less than an extent of the projection of the magnet arrangement onto the entrance plane in a width direction.

### FIELD OF THE INVENTION

The present invention relates to an electron trap, x-ray detector and apparatus for reducing the incidence of electrons on a detection element of an x-ray detector in x-ray analysis of a specimen.

### BACKGROUND

Scanning electron microscopes are commonly used to image specimens. This is typically performed by scanning a specimen surface with a focused beam of electrons and measuring signals generated by the interaction of electrons with the specimen to construct an image. In some applications, characteristic x-rays are measured using an x-ray detector in order to determine an elemental composition of the specimen.

FIG. 1 shows an exemplary apparatus for x-ray analysis using an electron microscope (EM) 100. X-ray analysis may be conducted in principle in any apparatus using an incident beam of charged particles (e.g. electrons or ions) and although the following description refers to electrons, the same principles apply in any charged particle apparatus.

An x-ray spectrum is measured by sensing, and measuring the energies of, individual x-ray photons emitted by a specimen 101 when it is hit by a focused electron beam 102. Each emitted x-ray photon is a particle having an associated energy, and this energy is typically converted into a measurable charge using a solid-state detector 105, said charge being proportional to the energy of the x-ray photon. The charge associated with an incident x-ray photon is then measured so that a count can be recorded, and a histogram of recorded measurements is generated to represent a digitised x-ray energy spectrum. Characteristic peaks of chemical elements can be identified in the x-ray energy spectrum, and the energies at which the peaks are recorded are used as a basis for determining an elemental content of the specimen material 101 under the electron beam 102.

As a result of the electron beam 102 interacting with the specimen 101, x-ray photons are emitted in all directions. However, the x-ray detector can only detect photons falling within a cone defined by the active area of the sensor within the x-ray detector. The higher the solid angle defined by this cone, the greater the signal that can be collected. Accordingly, a large collection solid angle is highly desirable. For a fixed x-ray detector active area, the solid angle can be increased by positioning the sensor closer to the specimen. However, moving the sensor towards the specimen is precluded by space constraints, namely the tube structure containing the sensor would collide with the pole piece 104 and/or the stage/sample 103. A collision point with the pole piece 104 is shown by way of example at point A in FIG. 1. It is noted that FIG. 1 is a schematic illustration only, and in practice, the sensor is typically positioned closer to the sample than is illustrated. Therefore, it is desirable to minimise the external diameter of the detector tube (shown at B in FIG. 1) to allow the detector to be located closer to the specimen without being restricted by the conical pole piece of the electron microscope.

BSEs are those electrons from the incident electron beam that are scattered predominantly elastically within the specimen and escape the surface travelling in a variety of directions. Consequently, a proportion of the BSEs are scattered such that they travel towards the x-ray detector 105, and the energy of these BSEs can be as high as those in the incident electron beam. Because these BSEs can cause damage to the x-ray sensor and can interfere with the measurement of the x-ray spectral emissions from the specimen, it is common to provide an electron trap 105a comprising an arrangement of magnets in front of the detector to deflect electrons away from the x-ray sensor.

Most existing magnetic electron deflector solutions use a pair of permanent magnets to deflect the BSEs away from the x-ray sensor.

In U.S. Pat. No. 4,382,183, and with reference to FIG. 1 thereof, an opposing pair of permanent magnets are connected by a yoke 12. Electrons P, which would otherwise travel towards the sensor 6, are deflected into a region lying between the magnets and sensor where they fall on a grooved absorbing surface that prevents them scattering towards the sensor. A vacuum supporting window is shown at 7 in FIG. 1 and the grooves also help prevent any x-rays, generated by electrons hitting the absorber, from reaching the sensor. X-rays from the specimen 2 have an unrestricted path 1 to the sensor 6.

One problem with this arrangement is the length of the trap, which prevents the sensor 6 being placed close to the specimen 2.

An additional problem with conventional magnetic electron traps is that the external field produced by the magnet influences the focused electron beam in the EM.

While some of the disadvantages above can be addressed by replacing a magnetic electron trap with a filter membrane positioned across the x-ray detector to absorb incident electrons, these filters are typically made of polymer materials which also attenuate low-energy x-rays. Low energy x-rays are particularly important for detecting light elements, therefore making filter membranes unsuitable in many x-ray analysis applications.

In U.S. Pat. No. 6,653,637, a charged particle trap is provided in which additional permanent magnets are introduced in order to cancel the external field that could influence the focused electron beam. One embodiment describes an arrangement suitable for a circular detector sensor with area 10 mm² where the maximum field for diverting electrons at the centre of the gap is 0.3 T. A further embodiment provides a larger aperture sufficient to allow x-rays to fall on a sensor with area 30 mm² where the maximum field is 0.2 T for deflecting electrons and where the external field is small enough not to interfere with EM operation. However, if larger sensor is to be used, then the aperture must be increased still further.

If the embodiment illustrated by FIG. 6 of U.S. Pat. No. 6,653,637 were scaled to provide an aperture large enough to expose a sensor with active area of 80 mm² without changing the length of the trap, the field between the magnets that deflects the electrons would be substantially reduced, the leakage field that influences the focused electron beam would be substantially increased, and the overall diameter of the external tube for the trap would be increased. Consequently, it would be more difficult to position the sensor close to the specimen because of collision with the pole piece at points such as A in FIG. 1 herein.

To address some of the disadvantages described above, a charged particle filter in U.S. Pat. No. 8,049,182 provides a magnetic deflector having a Halbach-type configuration of magnets around a bore of the filter. The Halbach configuration provides suitably uniform magnetic field within a bore of the filter, and also acts to minimise a stray field outside of the deflector. The magnetic deflector in U.S. Pat. No. 8,049,182 also provides inner and outer surfaces which taper as a respective function of distance towards a specimen in use, thus allowing the detector to be brought closer to the specimen.

However, to achieve the benefits provided by a Halbach configuration of magnets, namely that a magnetic field inside the Halbach configuration is suitably uniform and a magnetic field strength outside the Halbach configuration is suitably reduced, it is generally accepted that the arrangement of magnets is provided in a generally cylindrical geometry. Practical Halbach configurations of magnets are typically an approximation of the ideal Halbach cylinder, that being a cylinder of infinite length and having a magnetization orientation which is continuously varied around the circumference of the cylinder. A magnet array of generally cylindrical geometry still limits how close the electron trap can be brought to the specimen in use, owing to its extent in directions perpendicular to the detection axis of the detector—such a geometry being required in order to provide a magnetic field inside the filter suitable for preventing electrons from reaching the x-ray detector.

Therefore, what is needed is an improved means of preventing electrons from reaching an x-ray detector whilst mitigating the deleterious effects associated with the existing approaches discussed above.

### SUMMARY OF INVENTION

In a first aspect of the invention, there is provided an electron trap for use in a system for performing x-ray analysis of a specimen, comprising: a magnet arrangement comprising a first set of two opposing magnetic elements and a second set of two opposing magnetic elements, the magnetic elements arranged so as to define an interior region therebetween such that when in use, electrons travelling from the specimen and received by the electron trap enter the interior region through an entrance plane at a receiving end of the electron trap, the entrance plane being perpendicular to a longitudinal axis of the magnet arrangement; wherein an extent of a projection of the magnet arrangement onto the entrance plane in a height direction is less than an extent of the projection of the magnet arrangement onto the entrance plane in a width direction.

It has been found by the inventors that, for the purpose of trapping electrons, some effects of a cylindrical Halbach arrangement of magnets, namely the uniformity of the magnetic field throughout the interior of the arrangement, can be dispensed with, in favour of a magnet arrangement having a projection onto the entrance which has an extent in a height direction that is less than an extent in a width direction, while still providing a magnetic field distribution both inside and outside of the magnet arrangement to sufficiently deflect electrons, rendering these suitable for typical x-ray analysis apparatus and experiments. It follows from characteristics of the projection of the magnet arrangement onto the entrance plane that the shape of a trap comprising the arrangement, or a minimum bounding box surrounding the magnet arrangement, also has an extent in a height direction that is less than an extent in the width direction. In this way, advantageously, an electron trap is provided with a reduced extent in the height direction, thereby allowing the electron trap and an associated x-ray detector to be positioned closer to a specimen in use and making more efficient use of the space available in a typical particle analysis system.

Since the space available to magnetic deflectors in use is usually restricted in the direction between the polepiece and specimen stage, but is less limited in other directions, away from the polepiece and specimen stage, magnetic deflectors and x-ray sensors that depart from a generally cylindrical geometry and/or circular cross section may advantageously make more efficient use of the available space. Contrary to conventional approaches in which magnet elements are deliberately positioned in highly symmetrical formations, the electron trap according to the present disclosure may include magnet elements that are provided in a geometrical formation that has no more than two axes of reflectional symmetry.

It will be understood that neither the electron trap itself, nor the plurality of magnets comprised by the arrangement, need necessarily be defined by this limitation upon axes of symmetry. Rather, this feature pertains to the specific geometrical formation according to which the elements are configured and/or positioned relative to one another. For example, it will be appreciated that positioning magnet elements in formations such as a circle or a square, which have more than two axes of reflectional symmetry, would not provide the advantages described above, namely allowing the detector to be positioned closer to the specimen in use and increasing the solid angle for a detector having an equivalent active area. Further increases in solid angle and space efficiency may be provided by pairing an electron trap having the non-circular/non-square arrangement described above with a non-circular/non-square x-ray detection element in use. Concordantly, a nominally asymmetrical electron trap comprising an arrangement in which the elements are positioned according to a square or circular formation, and in which the number of axes of symmetry of the trap itself is nevertheless reduced to two or fewer by the introduction of other asymmetries in the arranged elements or asymmetrically placed features of the trap, would be understood to lack the above-described advantageous features of the electron trap according to the first embodiment. It will be understood also that the formations and geometries discussed in the foregoing refer to the two-dimensional projections of the magnet arrangements onto the entrance plane of the electron trap, or to two-dimensional cross sections perpendicular to a longitudinal axis or a view axis of the trap.

The degree to which magnet arrangements described herein are non-square/non-circular may be quantified by an aspect ratio of the projection of the magnet arrangement onto the entrance plane. Typically, a height to width ratio, that is, an extent in the height direction compared to an extent in the width direction of the projection onto the entrance plane, may be at most 1:5, and at least 4:5, with preferable examples at 1:1.5, 1:2, and 1:3.

As is described in more detail later in this disclosure, in typical embodiments the height and width dimensions of the magnet arrangement scale linearly along the length of the trap, decreasing towards the entrance plane. It will therefore be understood that the term “formation” as used herein generally refers to the particular pattern, that is the relative position and orientation, of magnetic elements within a plane orthogonal to the elongate axis of the trap, that is within a cross-section of the magnet arrangement. Typically, the arrangement remains the same along the length of the magnet arrangement, or at least throughout a portion, preferably a major portion, and preferably a central portion, of its length. Each of the example traps described in this document uses a single arrangement in this way. However, it is envisaged that some traps may include two or more different arrangements. More generally, it is possible for a trap to comprise a plurality of magnet arrangements. Thus the trap may comprise more than one formation, by way of comprising multiple magnet arrangements assembled sequentially along its length (i.e., along the view axis), forming a structure made up of distinct sections, wherein each section may comprise a respective arrangement of magnets. In such embodiments, any magnet arrangement of the plurality of arrangements may have a different formation or the same formation as another of the plurality of arrangements.

For instance, a trap could be divided into two or more sections along its length, with each section comprising a distinct arrangement of magnets. The first section, proximal to the entrance plane, might be provided with a formation that maximizes the space efficiency, that is minimizes the external size, of that section, while the second or any further sections could utilize a less spatially efficient configuration that produces a stronger internal field or weaker external field, for example.

In embodiments where a trap comprises an assembly of multiple magnet arrangements, the overall tapering form of the trap may or may not be maintained. This tapering form generally conforms to the collection solid angle for signals received by the detector from a sample in use.

Based on the realisation by the inventors that suitable magnetic field distributions can be provided to sufficiently deflect electrons without requiring the high level of magnetic field uniformity within the interior region that is associated with current Halbach configurations, electron traps may be designed with fewer magnetic segments, thus further reducing the complexity of the electron trap. In some embodiments, the magnet arrangement may comprise a first set of exactly two opposing magnetic elements, a second set of exactly two opposing magnetic elements, and no further magnetic elements. However, as described later in this disclosure, in some embodiments the arrangement comprises one or more further sets of magnetic elements. A set of two magnetic elements may be referred to as a pair of magnetic elements, in the sense that it comprises elements that are grouped together, typically on opposing sides of the arrangement, and generally having identical or similar directions of magnetic orientation. The elements of a pair may be identical, similar, or different in any one or more of their material composition, physical dimensions, and magnetic energy.

A set may comprise at least two magnetic elements. For instance, in some embodiments, an element of a set may be provided adjacent or proximal to one or more further elements such that those elements have identical or similar positions and/or magnetic orientation directions and together contribute similarly to the field in the interior region. A magnetic element is typically provided as a discrete, preferably continuous, portion of magnetic material. However, it is envisaged that a magnetic element may be discontinuous, formed of a plurality of sub-elements, that is multiple discrete portions of magnetic material arranged together.

It has also been discovered that, unlike typical Halbach configurations, the sets of opposing magnets do not need to have the same magnetic energy as each other but may still achieve a suitable redirection of stray field outside the electron trap away from the electron beam.

The electron trap according to the first aspect is suitable for use in an apparatus for performing x-ray analysis of a specimen, and is interposed in use between the specimen and an x-ray detector of the apparatus. In such an apparatus, a proportion of x-rays and electrons generated from an interaction between the specimen and the beam of the instrument travel from the specimen and are received by the electron trap. The electrons and x-rays enter the interior region through the entrance plane at a receiving end of the electron trap. The electrons may travel at least part of the way through the interior region on a path towards the x-ray detector. That is, electrons which are received by the electron trap may travel at least part of the way through the interior region on a path towards the x-ray detector.

The interior region defined by the magnet arrangement is typically a volume, preferably a continuous volume, which is traversable by electrons, such that electrons received by the electron trap are able to enter and move throughout the interior region under the influence of the magnetic field generated by the magnet arrangement. The interior region is preferably configured to permit electron propagation such as this throughout its extent.

The interior region may be a volume which is bounded by inward-facing surfaces of elements of the magnet arrangement. However, the interior region is typically distinct from other regions which are geometrically enclosed by magnetic elements but contain intervening solid structures that would interrupt the propagation of electrons.

The interior region defined by the magnet arrangement may be an aperture, typically extending from the entrance plane, through which electrons received by the electron trap are able to propagate under the influence of the magnetic field generated by the magnet arrangement, and typically throughout which x-rays may pass substantially unimpeded.

Whilst the trajectories of x-ray photons are not affected by the magnetic field present within the interior region, electrons from the specimen which enter the interior region are deflected by the magnetic field. This deflection results in, for a majority, and ideally all, of those electrons, modified trajectories which result in the electrons not reaching an active area of the x-ray detector. The electrons travelling from the specimen and received by the electron trap are typically backscattered electrons. Whilst the electron trap according to the invention may be used with many conventional x-ray detector setups, a non-circular x-ray detection element is preferred so as to further optimise the usage of the available space and provide a greater active area of the detection element having line of sight to the specimen in use.

The magnet arrangement of the electron trap is typically provided such that a relatively high magnetic flux density is provided within the interior region, and a relatively low magnetic flux density is provided outside of the electron trap. As illustrated in the examples of the invention provided herein, such a magnetic field can be achieved through the magnet arrangement comprising two sets of opposing magnetic elements without requiring the magnet arrangement to have a generally cylindrical geometry as is typically associated with a Halbach arrangement.

In some embodiments, the magnet arrangement further includes a shielded housing made of a material of high permeability. The housing is typically provided so as to cover or surround the exterior surfaces of the magnetic elements, and may assist in redirecting magnetic flux away from the electron beam in use. This is because the magnetic flux follows the path of least magnetic reluctance. In various embodiments the housing may be formed from or comprise any one of: soft iron, mild steel (optionally annealed), a material comprising at least 99.85% by weight of iron and not more than 0.02% by weight of carbon, 0.05% by weight of manganese, 0.005% by weight of sulphur, 0.005% by weight of phosphorus, 0.05% by weight of silicon, 0.03% by weight of copper, 0.01% by weight of nitrogen, and 0.03% by weight of oxygen, and a material comprising at least 48% by weight of iron and 48% by weight of cobalt, with not more than 2% by weight of vanadium. Typically the housing or at least a major portion thereof is formed from a material that, at a magnetic flux density of 1.5 Tesla, exhibits a relative permeability of 2,000 or greater, preferably 4,000 or greater, more preferably 7,000 or greater.

The first set of magnetic elements, second set of magnetic elements, and optionally any further set of magnetic elements are typically arranged such that for each magnetic element in said sets, a direction normal to a surface facing the interior region, typically a major surface facing the interior region, has a projection onto the entrance plane different from that of each other element. In typical embodiments where a set of magnetic elements comprises a pair of magnetic elements on opposing sides of the interior region or the central longitudinal axis of the magnet arrangement, the difference in the projections onto the entrance plane of the directions normal to a surface facing the interior region of those elements may include projections that are antiparallel.

A “major surface facing the interior region” of a magnetic element as described herein refers to a surface of the element facing the interior region that has a greater surface area than any remaining surfaces facing the interior region when the magnetic elements are arranged to define the interior region. Optionally, a surface facing the interior region of a magnetic element may be a surface which bounds the interior region.

A magnetic element being arranged such that a direction normal to a surface facing the interior region, typically a major surface facing the interior region, having a projection onto the entrance plane different from that of each other element preferably means that the direction normal to the surface facing the interior region differs sufficiently such that, in combination with the direction of magnetic orientation of the element, there is a material influence on the magnetic field distribution within the interior region. Magnetic elements according to this disclosure typically possess a direction of magnetic orientation which is parallel or perpendicular to a surface facing the interior region, although this is not mandatory.

For example, the second set of opposing magnetic elements may have surfaces facing/defining the interior region and directions of magnetic orientation which enhance the strength of the magnetic field generated by the first set of opposing magnetic elements inside the interior region. This enhancement in magnetic field strength is typically in portions of the interior region which are towards elements of the second set of magnetic elements.

Where a magnetic element comprises a plurality of sub-elements as discussed above, the surface (typically a major surface) of the magnetic element facing the interior region may be formed by a corresponding plurality of surfaces of those sub-elements. The direction normal to the surface of the magnetic element may be defined collectively, that is, in terms of the magnetic element as a whole, such that the surfaces are not required individually to have differing projections of their normal directions onto the entrance plane.

Each magnetic element comprised in the magnet arrangement may be angled with respect to an adjacent magnetic element so as to further enclose the interior region. The first set of magnetic elements and second set of magnetic elements, and optionally further sets of magnetic elements are typically arranged such that the magnet arrangement forms a non-circular ring, the space provided within the non-circular ring corresponding to the interior region.

The non-circular ring defined by the magnetic elements is preferably continuous in that, typically, the magnetic elements of the magnet arrangement abut together around the circumference of the non-circular ring, thus forming a closed non-circular ring.

In practice, however, manufacturing tolerances may necessitate that the non-circular ring defined by the magnetic elements is only substantially continuous, that is, each magnetic element may not be in contact with or abut against an adjacent magnetic element. As a result, the terms “closed” and “continuous” as used herein to refer to an arrangement of magnetic elements may mean substantially closed or substantially continuous respectively, allowing for the fact that manufacturing tolerances may prevent a fully closed or continuous arrangement of magnetic elements. Unless otherwise specified, the dimensions, relative positioning, orientation, and magnetization direction of the components described herein are manufactured to standard mechanical tolerances consistent with ISO 2768-mK. This includes both linear and angular tolerances. In preferred embodiments, angular tolerances are within ±1°, with typical implementations allowing deviations within ±2°, and in some cases up to ±5°, depending on functional requirements and manufacturing considerations.

The magnet arrangement is typically open at two opposing ends which are provided at two opposing ends of the electron trap respectively so as to provide lines of sight through the trap, between the specimen and the x-ray detector when in use. One open end of the magnet arrangement corresponds to the receiving end the electron trap which faces the specimen in use and is the end of the electron trap through which electrons enter the interior region in use. The other open end of the magnet arrangement corresponds to a detector end of the electron trap at an opposite end of the electron trap to the receiving end. The detector end is proximal to the detection element of the x-ray detector, and the receiving end distal to the detector, when the trap is in use, and the receiving end is positioned proximal to the specimen and the detector end distal to the specimen in use. The interior region may be defined as a region throughout which unobstructed lines of sight may be provided between the specimen and detection element of the x-ray detector when the electron trap is interposed between the specimen and detector element in use. Elements of the magnet arrangement may be arranged such that the width and/or height of the interior region varies between the detector end and receiving end of the electron trap for at least a section along the longitudinal axis, generally tapering, typically linearly, towards the receiving end. In this way, an area of the open end or face of the magnet arrangement at the receiving end of the trap may be less than an area of the open face of the magnet arrangement at the detector end of the trap. A typical height to width aspect ratio of the open end or face of the magnet arrangement at the receiving end of the trap may be 5:8.

The interior region may be further bounded by opposing planes located at each of the receiving end and the detector end of the electron trap, the planes typically being defined as perpendicular to a longitudinal axis of the magnet arrangement. The longitudinal axis may be further defined as a view axis or a detector axis, or as an axis passing through a centre of the receiving end and a centre of the detector end of the electron trap, and typically also extends in a direction between the specimen and the x-ray detector when the electron trap is in use. The plane at the receiving end of the electron trap is referred to as the entrance plane herein, and a plane at the detector end of the electron trap is referred to as an exit plane. The entrance plane may be defined as a plane orthogonal to the view/elongate axis of the trap. It will be understood that an entrance end (which may be understood as a receiving end) of the trap, or a portion of the entrance end may define or lie within the entrance plane in some embodiments, while in other embodiments, for example where an entrance end is angled with respect to the view/elongate axis of the trap, the entrance plane may coincide with only a part of or location within the entrance end.

The projection of the magnet arrangement onto the entrance plane as described herein may be defined as a geometric projection of the three-dimensional magnet arrangement onto a two-dimensional plane located at the receiving end of the electron trap. The extent of the projection of the magnet arrangement in the height and width directions may be equivalent to the maximum extent of the magnet arrangement in the height and width directions at any point along its length between the receiving end of the electron trap and the detector end of the electron trap.

In preferable embodiments, the magnetic elements are arranged such that a magnetic field attributable to the electron trap has a magnetic flux density of a magnitude greater than or equal to 1,000 Gauss within the interior region, and more preferably throughout the interior region. Preferably the magnetic elements are arranged such that the magnetic field attributable to the electron trap has a magnetic flux density of less than or equal to 10 Gauss outside of the electron trap between the entrance plane and a parallel plane at a detector end of the electron trap opposite to the receiving end. The parallel plane at a detector end of the electron trap opposite to the receiving end is equivalent to the exit plane as defined above. In other words, the configuration of magnets within the electron trap is such that, for the region between and defined by the entrance plane and the exit plane (that is, along the entire extent of the trap along its longitudinal or view axis), a minimum strength of the magnetic field attributable to the trap in the interior region is significantly greater, preferably by one or more orders of magnitude, than a maximum strength of the magnetic field attributable to the trap, external to the trap. Preferably the ratio of these minimum internal and maximum external field strengths is 100:1. This difference in the magnitude of the strength of the magnetic field attributable to the magnet arrangement within and outside of the interior region ensures effective charged particle deflection inside the interior, as well as a reduced magnetic effect on the electron beam and other equipment outside of the trap, in a typical apparatus while providing for a sufficiently compact (thin) trap design.

The magnetic elements according to this disclosure may be arranged such that, for any given magnet, the direction of magnetic orientation is the same as that of the magnet positioned opposite it (i.e. on an opposing side of the interior region, or the central longitudinal axis of the magnet arrangement). Two magnets, or two subsets of magnets, positioned opposite each other are typically defined as being a set of magnetic elements throughout this disclosure, typically including the first set of magnetic elements and second set of magnetic elements described above.

Each of the magnetic elements may be understood as having a respective direction of magnetic orientation. A direction of magnetic orientation of a magnetic element may be understood as the direction of its magnetization vector, or as being defined by the alignment of its magnetic dipole. The direction may be thought of as pointing from the south pole to the north pole inside the material of the magnet. Preferably, a vector sum of the directions of magnetic orientation of the magnetic elements comprised by or defining the first set of magnetic elements has an opposite direction to that of a vector sum of the directions of magnetic orientation of the magnetic elements comprised by or defining the second set of magnetic elements. Preferably, a projection onto the entrance plane of the vector sum of the directions of magnetic orientation of the first set of magnetic elements is parallel to the height direction.

Providing sets of magnetic elements having generally opposite directions of magnetic orientation allows stray fields outside of the interior region to be further minimised, thereby reducing any potential effect on the electron beam and other sensitive equipment. Using the Halbach principle of “redirecting” at least some of the stray fields back into the trap also allows the design of suitable magnet arrangements with less magnetic material, thinner shielding, or both.

The term “opposite” as used herein may mean substantially opposite (e.g. allowing for manufacturing tolerances) or may refer to a specific range of angles/directions. For example, an obtuse angle formed between projections of the directions of magnetic orientation of each element of the first set of magnetic elements onto the entrance plane, and projections of the directions of magnetic orientation of each element of the second set of magnetic elements onto the entrance plane may be between 160 and 180 degrees, preferably between 170 and 180 degrees, or more preferably between 175 and 180 degrees.

The terms “orthogonal” and “perpendicular” as used herein may mean substantially orthogonal or perpendicular respectively (e.g. allowing for manufacturing tolerances) or may refer to a specific range of angles/directions. For example, where two directions are described herein as orthogonal or perpendicular, an angle formed between the two directions may be between 80 and 100 degrees, or more preferably between 85 and 95 degrees.

The terms “parallel” and “collinear” as used herein may mean substantially parallel or collinear respectively (e.g. allowing for manufacturing tolerances) or may refer to a specific range of angles/directions. For example, where two directions are described herein as parallel or collinear, an obtuse angle formed between the two directions may be between 170 and 180 degrees, or more preferably between 175 and 180 degrees. The terms “parallel” and “collinear” as used herein also do not imply that two directions described as such must be the same, that is, they are also intended to include directions that are opposite or substantially opposite to each other.

In typical embodiments, a set of elements, and preferably each set, is provided as a pair of two elements. Thus each set may be arranged as a pair of opposing sides of a rectangular or quasi-elliptical (“racetrack”) formation. In such embodiments, the advantageous opposing directions of magnetization may be effected by way of first and second sets being arranged so that their respective directions of magnetization are opposite, with each element in a set preferably having parallel magnetization directions. Preferably, therefore each element of the first set of magnetic elements has a direction of magnetic orientation, and typically a vector sum of the directions of magnetic orientation of the first set of magnetic elements is a first resultant direction of magnetic orientation, and each element of the second set of magnetic elements has a direction of magnetic orientation, and typically a vector sum of the directions of magnetic orientation of the second set of magnetic elements is a second resultant direction of magnetic orientation. The first resultant direction of magnetic orientation and the second resultant direction of magnetic orientation are typically opposite, and preferably a projection onto the entrance plane of the first resultant direction of magnetic orientation is parallel, or substantially parallel, to the height direction.

In embodiments where a set of magnetic elements comprises more than two elements, however, the projections onto the entrance plane of the magnetization directions (which may be referred to herein as a projected magnetization direction) of the elements of a set may or may not be parallel. Therefore, the projected magnetization direction of the first set opposing that the second may be effected by way of arranging the elements of a set such that the resultant or net projected magnetization direction, that is the vector summation of the projected magnetization directions of the first set, has an opposite direction to that of the second set. Accordingly, each set of magnetic elements may generally be thought of as comprising first and second subsets of magnetic elements, wherein a subset may comprise one or more magnetic elements. The first and second subsets are typically arranged on opposing sides of the interior region. Preferably, for each set, a direction of a vector sum of the projected directions of magnetic orientation of the first subset is parallel to a direction of a vector sum of the projected directions of magnetic orientation of the second subset. For example, embodiments are envisaged in which the magnet elements are arranged in an elongate hexagon formation, in which the first set is provided as a pair of magnets and the second set is provided as a pair of subsets of magnets, wherein the elements in a subset, and in particular their projected magnetization directions, are angled with respect to one another such that their resultant projected magnetization is opposite to the projected magnetization directions of the elements of the first set. It will be understood that a variety of formations, with a range of numbers of constituent magnetic elements, may be chosen in which the net projected magnetization directions of the first and second sets are opposite.

In some embodiments, each element of the first set of magnetic elements and second set of magnetic elements comprises a planar major surface facing the interior region, and typically, a planar major surface distal to the interior region. In some embodiments, a major surface distal to the interior region may not be planar, particularly embodiments where a set of magnet elements comprises more than two elements, particularly by way of comprising two opposing subsets of elements as is discussed in further detail below.

A surface of an element that faces the interior region may be thought of as a surface that defines the interior region, or a portion of the boundary thereof. The magnetic elements may be arranged such that a projection onto the entrance plane of a normal vector of the major surface facing the interior region of each element of the first set of magnetic elements is collinear with a first direction, and a projection onto the entrance plane of a normal vector of the major surface facing the interior region of each element of the second set of magnetic elements is collinear with a second direction.

In some embodiments, the first direction and second direction are orthogonal. In preferred embodiments, the directions normal to the major surfaces facing the interior region of the magnetic elements in each set of magnetic elements are non-orthogonal. In these embodiments, the magnet arrangements may define an internal region resembling a truncated pyramid with a polygonal (e.g. rectangular, octagonal) base. The height and/or width of the interior region may taper along the direction of the longitudinal axis between the detector end and the receiving end of the electron trap. Preferably the magnets are arranged such that planes containing the inward-facing major surfaces of the magnet elements converge at a point ahead of the entrance plane, that point typically corresponding to a specimen position in use. In this way, the geometry of the magnet arrangement may be optimized to maximize the solid angle over which a detection element has line-of-sight of the specimen through the trap while minimizing the space occupied by the trap.

As described earlier in this disclosure, however, some embodiments involve a set of magnet elements comprising more than two elements, particularly by way of comprising two opposing subsets of elements, wherein any of those subsets may comprise a plurality of elements. In such embodiments, for any of the first and second sets, a projection onto the entrance plane of a direction normal to a major surface facing the interior region of an element of a subset of two or more elements may be non-orthogonal to an element comprised by the other of the first and second sets. Nevertheless, in a given set of the first and second sets, it is advantageous for (the projection onto the entrance plane of) an average orientation of magnets in a subset of that set to be aligned with that of the opposing subset of that set, and to be orthogonal to that of a subset, and more so each subset, of the other of the first and second sets. Preferably, therefore for each of first and second opposing subsets of the first set of magnetic elements, a projection onto the entrance plane of a vector sum of directions normal to the major surfaces facing the interior region of each element of the subset is orthogonal to a projection onto the entrance plane of a vector sum of directions normal to the major surfaces facing the interior region of each element of a first subset of the second set, and is orthogonal to a projection onto the entrance plane of a vector sum of directions normal to the major surfaces facing the interior region of each element of a second subset of the second set. It will be understood that this orthogonality may apply to rectangular formations as well as those involving greater numbers of magnetic elements in which elements of a subset have inward-facing major surfaces angled with respect to one another, forming hexagonal and octagonal arrangements for instance. Accordingly, in these embodiments, any one or more of first and second opposing subsets of any one or more of the first and second sets may comprise exactly one magnetic element, exactly two magnetic elements, or a plurality of magnetic elements.

In some embodiments where a set of magnet elements comprises more than two elements, and particularly where a set of magnetic elements comprises a plurality of magnetic elements on opposing sides of the magnet arrangement, the additional magnetic elements may be arranged so as to define a more complex external surface of the magnet arrangement. That is, a major surface distal to the interior region formed by one or more elements of the first set or second set of magnetic elements may be more complex than the planar major surface distal to the interior region discussed above. For example, the external surfaces defined by the magnetic elements which are separated along the width direction of the magnet arrangement may be non-planar so as to permit additional magnetic material to be provided at these locations, thereby making more efficient use of the available space in the width direction compared to the height direction.

In some embodiments, particularly those in which the first and second sets of magnets are arranged in a rectangular formation, further advantages may be achieved by effecting various configurations at corners where magnets of the first and second sets contact or are proximal to one another. For the purposes of the following embodiments, the first set of magnets may be thought of as those arranged at the “top” and “bottom” of the trap, that is those separated along the height direction, and the second set of magnets may be thought of as those arranged at the “sides” of the trap, that is those separated along the width direction. However, it will be understood that these ordinals are arbitrary and that the sets of magnets may be enumerated differently for any of the embodiments described herein. It will also be understood that the embodiments now described may be thought of as defining the arrangement of magnet elements within a given cross-sectional plane orthogonal to the length of the trap, and that any of the following positional and geometrical relationships may be present within each of a plurality of such planes along the length of the trap, and are preferably present throughout the length of the trap or a portion thereof, for example where the relative arrangement of magnet elements along the length remains substantially the same, albeit changing in scale.

In some embodiments, the magnets of the second set may be sufficiently long, that is extensive along the height axis of the trap, relative to the spacing and thicknesses, or heights, of the magnets of the first set, that the elements of the second set of magnetic elements overlap the elements of the first set of magnetic elements. Accordingly, in some embodiments, a separation distance between each element of the first set of magnetic elements in the height direction is less than an extent of each element of the second set of magnetic elements in the height direction such that the major surfaces facing the interior region of each element of the second set of magnetic elements overlap with each element of the first set of magnetic elements. An end face, or a portion thereof, of a magnet of the first set may be arranged in contact with, or proximal to, a portion of an inward-facing major surface of a magnet of the second set. It has been found that overlapping configurations such as these permit a greater amount of magnetic material to be provided in the second set, for a trap of given dimensions or given space constraints, compared to configurations in which magnets meet only along their edges, for example. Consequently, in use, electrons entering a trap configured in this way that are deflected to the sides of the trap (towards the second set) experience a stronger field closer to those sides, resulting in their being deflected through smaller-radius trajectories, and thereby undergoing more collisions with the trap and so losing more energy. In this way the efficacy of the trap is increased compared to a trap of the same overall dimensions without such a corner joint configuration.

In other embodiments, corners of the arrangement are configured to overlap differently, with the magnets of the first set overlapping those of the second set in the width axis. Thus in some embodiments a separation distance between each element of first set of magnetic elements in the height direction is greater than an extent of each element of the second set of magnetic elements in the height direction such that the major surfaces facing the interior region of each element of the first set of magnetic elements overlap with each element of the second set of magnetic elements. The inventors have found that the manner in which the magnetic elements, and optionally any housing present around the magnetic elements, abut against each other allows the direction and strength of the magnetic field both inside and outside of the interior region to be controlled. Arranging the second set of magnets interposed between, and preferably contacting, major surfaces of the magnets of the first set of magnets advantageously increases the reluctance of the magnetic path towards a housing of the trap, compared to arrangements in which the magnets meet at their edges for instance. This has been found to increase the strength of the internal field near the side, that is the second set of, magnets.

Typical embodiments include polyhedral magnet elements, such as elements having trapezoidal cross-sections, in part for reasons of ease of manufacture. However, it will be understood that the primary advantage provided by the magnet arrangements described herein is not dependent on a specific element shape. In particular, magnet elements need not necessarily be polyhedral in shape, or comprise, exclusively or otherwise, planar or polygonal surfaces, or (exclusively) straight edges.

In fact, it may be advantageous in some embodiments for one or more of the magnet elements to have a curved shape. Arrangements comprising curved magnets may be provided in which the shape of the interior volume defined by the magnets conforms more closely to the solid angle of detection of the detection element in use than may be achieved using polyhedral magnets. That is, by adopting curved shapes, the magnet elements may more effectively mimic the collection angle, thereby maximizing the magnet and shielding material for maximum field strength and minimum leakage. As with the other geometrical characteristics of the magnet arrangements disclosed herein, the description of this curvature is primarily described with reference to a two-dimensional representation, such as a cross section orthogonal to the trap orthogonal axis, of the arrangement. Accordingly, it will be understood that in typical embodiments in which the magnet arrangement is provided in an oval formation, that formation, as with other preferred embodiments employing alternative formations, remains the same throughout the arrangement along the longitudinal direction, while its dimensions, and accordingly the radius of curvature of the curved magnets decreases towards the exit plane.

Various embodiments are envisaged in which any of the first and second sets of magnets, or any magnets included in the magnet arrangement, can have a curved shape. For instance, the first set of magnets may include trapezoidal (in their cross-section) magnets having planar surfaces, at least on their inward-facing sides, while the second set of magnets may be formed from an outward-curving pair of magnets. In some embodiments, therefore, each element of the second set of magnetic elements comprises a curved major surface facing the interior region, and more preferably a correspondingly and/or conforming opposite (that is, outward-facing) major surface also. Such a configuration may be thought of as an “oval” arrangement, which provides advantages in terms of optimizing the space occupied by the trap against the collection angle of a detector element used with the trap, together with the beneficial field strength and efficiency. In some such configurations, a curved second set of magnet elements is combined in the arrangement with a straight first set of elements, to provide a “racetrack” formation.

For magnetic elements which comprise a curved surface, typically a curved major surface, facing the interior region, a direction normal to the surface facing the interior region may be a direction selected from the range of normal directions defined by that surface.

In arrangements wherein one or more portions of the magnet arrangement is curved, it is preferable for each set of magnets, or at least one of the sets of magnets, to include a plurality of subsets of magnets. Alternatively, it may be considered that one or more magnet elements thereof can be provided as a plurality of sub-elements. This allows the respective sub-elements' directions of magnetization and the resulting directions of magnetization for each element and set of elements to be configured appropriately in order to achieve the desired field. By dividing the magnet sets into subsets or the elements into sub-elements, the magnetization orientation can be configured to optimize the magnetic field within the interior region, enhancing the performance of the electron trap.

Preferably, each element of the first set of magnetic elements abuts each element of second set of magnetic elements so as to reduce a leakage of magnetic flux from the interior region, that is to reduce the magnetic flux directed into the housing and increase the flux directed into the trap itself, in particular the interior region. As described above, manufacturing tolerances may prevent all magnetic elements in a magnet arrangement from abutting together. In this case, it is preferable to position adjacent magnets as close together as permitted by the manufacturing tolerances in order to reduce a leakage of magnetic flux from the interior region.

Other joint configurations are envisaged, for rectangularly formed arrangements and otherwise. For example, adjacent magnetic elements, whether in the same set or different sets, may be configured with end-to-end joints, that is meeting at their end faces, for example at mitre joints for corner interfaces. Generally, for a plurality, and more preferably all, of the magnetic elements comprised by the arrangement, each magnetic element has a pair of opposing end faces. Each end face may be angled, typically about the longitudinal axis. Preferably the elements are arranged in a polygonal configuration, more preferably a closed polygonal configuration, such that the angled end faces of adjacent beams abut one another to form a continuous joint. The angles of the end faces may be advantageously configured to effect a complementary fit between adjacent elements.

Typically, the closed polygonal configuration is a quadrilateral, preferably a rectangle. Various closed polygonal configurations are envisaged, however, including hexagonal and octagonal formations.

In some embodiments, the magnet arrangement further comprises a third set of two opposing magnetic elements and a fourth set of two opposing magnetic elements arranged so as to further define the interior region therebetween, each element of the third set of magnetic elements and fourth set of magnetic elements being arranged between an element of the first set of magnetic elements and an element of the second set of magnetic elements. Providing additional third and fourth sets of magnetic elements may further increase the field strength of the magnetic field generated inside the interior region and may further assist in reducing a stray magnetic field outside of the interior region. The magnet arrangement may comprise a first set of exactly two opposing magnetic elements, a second set of exactly two opposing magnetic elements, a third set of exactly two opposing magnetic elements, a fourth set of exactly two magnetic elements, and typically no further magnetic elements.

Typically, each element of the third set of magnetic elements and fourth set of magnetic elements is arranged between an end surface of an element of the first set of magnetic elements and an end surface of an element of the second set of magnetic elements. In this way, the first, second, third, and fourth sets of magnetic elements may form a non-circular ring, the space provided within the non-circular ring corresponding to the interior region. The non-circular ring defined by the magnetic elements is preferably continuous or substantially continuous (allowing for manufacturing tolerances) and may have a cross-section perpendicular to the longitudinal axis that is octagonal, preferably an elongate octagon, or generally an irregular octagon. Each element of the third set of magnetic elements and fourth set of magnetic elements may abut against an end surface of an element of the first set of magnetic elements and an end surface of an element of the second set of magnetic elements. It will be understood that any two abutting magnetic elements may be provided such that a part, such as one or more of a surface, edge, or vertex, of one of the two elements is in contact with a part, such as one or more of a surface, edge, or vertex, of the other element. Preferably, the contact between two adjacent elements is across a contact area, typically at the ends of elongate elements, so as to provide greater redirection of magnetic flux therethrough.

Preferably, each element of the third set of magnetic elements has a direction of magnetic orientation, and typically a vector sum of the directions of magnetic orientation of the third set of magnetic elements is a third resultant direction of magnetic orientation, and each element of the fourth set of magnetic elements has a direction of magnetic orientation, and typically a vector sum of the directions of magnetic orientation of the fourth set of magnetic elements is a fourth resultant direction of magnetic orientation, wherein the third resultant direction of magnetic orientation and the fourth resultant direction of magnetic orientation are orthogonal. The third resultant direction of magnetic orientation and fourth resultant direction of magnetic orientation are typically different from the first resultant direction of magnetic orientation and second resultant direction of magnetic orientation. This arrangement of magnetic elements and magnetic orientations further increases the ability of the magnet arrangement to reduce a magnetic field strength outside of the interior region through field cancellation.

Preferably, a projection onto the entrance plane of the first resultant direction of magnetic orientation is parallel to the height direction, and projections of the third resultant direction of magnetic orientation and fourth resultant direction of magnetic orientation onto the entrance plane each form a non-zero angle to the width direction. It has been found that the external, that is stray, field attributable to traps in which corner magnets are so configured is lower than traps comprising some alternative arrangements. Projections of the third resultant direction of magnetic orientation and fourth resultant direction of magnetic orientation onto the entrance plane may also each form a non-90 degree angle to the width direction, since this would be aligned with projections of the typical magnetic orientations associated with the side magnetic elements.

Preferably, projections of the third resultant direction of magnetic orientation and/or the fourth resultant direction of magnetic orientation onto the entrance plane each form an angle to the width direction of between 5 and 85 degrees, more preferably between 10 and 80 degrees, more preferably between 15 and 75 degrees, more between preferably 20 and 70 degrees, more preferably between 25 and 65 degrees, more preferably between 30 and 60 degrees, more preferably between 45 and 50 degrees, and, more preferably still, forms an angle of 50 degrees to the width direction. The inventors have observed that effecting such directions of magnetic orientation provides a significant improvement in the generated field strength inside the interior region (both at a given point and averaged across the interior region).

In some embodiments, ferromagnetic material is disposed adjacent to major surfaces distal to the interior region of each element of the third set of magnetic elements and fourth set of magnetic elements. For arrangements in an octagonal formation, for instance, this additional ferromagnetic material advantageously allows for thicker ferromagnetic housing in the corners of the trap. Compared to a magnet arrangement in which the operative field is provided only by two pairs of magnetic elements, additional space may thus be provided between the magnet arrangement and the minimum bounding box defined by the magnet arrangement. The third and fourth sets of magnetic elements and fourth set of magnetic elements may be provided with ferromagnetic material so as to further shield the magnet arrangement and reduce a magnetic field generated outside of the interior region.

In some embodiments, the magnet arrangement further includes a fifth set of two magnetic elements, wherein each element of the fifth set of magnetic elements is arranged adjacent to a major surface distal to the interior region of each element of the second set of magnetic elements respectively. Preferably, each element of the fifth set of magnetic elements has a direction of magnetic orientation that is parallel, or substantially so, to a direction of magnetic orientation of an adjacent element of the second set of magnetic elements. By increasing the magnetic energy adjacent to each element of the second set of magnetic elements, a distribution of the magnetic field within the interior region can be further shaped so as to concentrate it in parts of the interior region proximal to the second set of magnetic elements. Including in the arrangement the fifth magnetic elements in the manner described above may have an equivalent effect to increasing a thickness of each element of the second set of magnetic elements.

Typically, the magnetic elements have geometries such that they can be arranged to form a closed (or substantially closed in view of manufacturing tolerances) non-circular ring requiring only a small number (e.g. 4 or 8) of magnetic elements to define the interior region. Each magnetic element may adjoin to an adjacent magnetic element in a complementary fashion, for example in a mosaic like fashion.

In some examples, an average thickness of each element of the first set of magnetic elements is less than an average thickness of each element of the second set of magnetic elements. Alternatively, or additionally, a maximum thickness of each element of the first set of magnetic elements is less than an average thickness of each element of the second set of magnetic elements.

While in principle a magnetic element described in this disclosure may be provided in the form of an electromagnet, the magnetic elements are typically provided as a portion of permanent magnetic material, that is, composed of a permanent magnetic material. It will be understood that such magnet elements are practical for the present application. Typically, a magnetic energy of each element of the first set of magnetic elements is greater than or equal to a magnetic energy of each element of the second set of magnetic elements. In some embodiments, magnetic elements may comprise of be formed from a neodymium-based (NdFeB) magnetic material.

As alluded to above, the available space in which to locate the x-ray detector and electron trap in use is restricted by the pole piece, stage movement and adjacent detectors. These limitations dictate that external dimensions of electron traps in EDS systems typically measure less than 5 cm, decreasing to around 1-2.5 cm for traps working in close proximity to the specimen. Accordingly, the magnet arrangements herein are typically provided having fewer than or equal to 20 magnetic elements, more preferably fewer than or equal to 16 magnetic elements.

In a second aspect of the invention, there is provided an x-ray detector, comprising: a detection element; and an electron trap according to the first aspect or any implementation of the first aspect. The detection element is typically one of a silicon drift detector, a PIN diode detector, a gas proportional counter, a CCD array, and a CMOS array.

The detection element is preferably non-circular and non-square, and/or may have a non-circular and non-square active area. Preferably, the detection element has an extent in the height direction less than an extent in the width direction. Such a non-circular and non-square detection element and/or active area may complement the arrangement of the electron trap so as to further optimise the use of available space between the pole piece and specimen stage in use, and to provide a greater active area having line of sight to the specimen in use.

In a third aspect of the invention, there is provided an apparatus for analysing a specimen, the apparatus comprising: an electron beam assembly for generating a focused electron beam comprising a polepiece; and an x-ray detector according to the second aspect or any implementation of the second aspect.

In use, one of the first set of magnetic elements is positioned adjacent to the pole piece of the electron beam assembly. In this positioning of the electron trap, the reduced extent of the magnet arrangement in the height direction compared to the width direction allows the electron trap and x-ray detector to be positioned closer to the specimen, thus increasing the solid angle of collection.

For advantages associated with the second and third aspects of the invention, please refer to the advantages associated with the corresponding implementations of the first aspect of the invention.

It will be understood that the term “height direction” as used in this disclosure does not necessarily correspond to a vertical direction, or alignment with the direction of gravity, or to any particular orientation with respect to an external reference frame. The height direction of the trap is defined in relation to the reference frame of the trap itself, as is the (typically orthogonal) width direction. The height and width directions are typically orthogonal to the longitudinal axis of the trap, and any of the entrance plane and the exit plane may be defined as being spanned by two vectors that are respectively parallel to the height and width directions. Nevertheless, it is envisaged that, when in use with typical electron microscope arrangements, the trap is oriented such that the width direction is aligned, or substantially so, with a horizontal direction. It is similarly envisaged that, when the trap is in use, its height direction is orthogonal to the horizonal direction, and typically forms a non-zero angle with the vertical direction, as the longitudinal axis, and the view axis of a coupled detector, are inclined so as to monitor a specimen.

### BRIEF DESCRIPTION OF DRAWINGS

The file of this patent contains at least one drawing executed in color. Copies of this patent with color drawing(s) will be provided by the Patent and Trademark Office upon request and payment of the necessary fee.

Examples of the present invention will now be described, with reference to the accompanying drawings in which like features are labelled with like reference signs, and in which:

FIG. 1 shows schematically an arrangement for x-ray analysis according to the prior art;

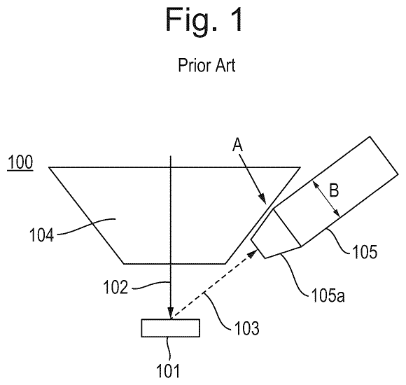

FIG. 2 shows schematically a magnet arrangement of an electron trap according to a first example of the invention;

FIG. 3 shows schematically a magnet arrangement of an electron trap according to a second example of the invention;

FIG. 4 is a graph showing a simulated variation in the magnitude of the magnetic field (B-field) in a nominal Z direction along a nominal Y axis for different exemplary magnet arrangements according to the invention and a comparative example of a 2-bar magnet;

FIG. 5 is a graph showing a simulated variation in the absolute value of the magnitude of the magnetic field (B-field) in a nominal Z direction along a nominal X axis for different exemplary magnet arrangements according to the invention and a comparative example of a 2-bar magnet arrangement;

FIG. 6 shows schematically a magnet arrangement of an electron trap according to a third example of the invention;

FIG. 7 shows schematically a magnet arrangement of an electron trap according to a fourth example of the invention;

FIG. 8 is a graph showing simulated variations in the magnitude of the magnetic field (B-field) along a nominal U axis in the exemplary magnet arrangements illustrated in FIGS. 6 and 7;

FIG. 9 is a graph showing simulated variations in the magnitude of the magnetic field (B-field) along a nominal U axis in the exemplary magnet arrangement illustrated in FIG. 6 for different ratios of magnetic energy between the first set of two magnetic elements and the second set of two magnetic elements;

FIG. 10 shows schematically a magnet arrangement of an electron trap according to a fifth example of the invention;

FIG. 11 is a graph showing simulated variations in the magnitude of the magnetic field (B-field) along a nominal U axis in the exemplary magnet arrangement illustrated in FIG. 10 for different magnetization orientations of a third set of two magnetic elements and fourth set of two magnetic elements;

FIG. 12 is a graph showing a simulated average magnitude of the magnetic field (B-field) within the interior region in the exemplary magnet arrangement illustrated in FIG. 10 for different magnetization orientations of the third set of two magnetic elements and fourth set of two magnetic elements; and

FIGS. 13 and 14 are perspective views of magnet arrangements according to sixth and second examples of the invention respectively.

### DETAILED DESCRIPTION

Example magnet arrangements and graphs illustrating features of the magnetic fields generated by said magnet arrangements are now described. The magnet arrangements described below are suitable for use as part of an electron trap for an x-ray detector, which may itself be used in an apparatus for performing x-ray analysis of a specimen.

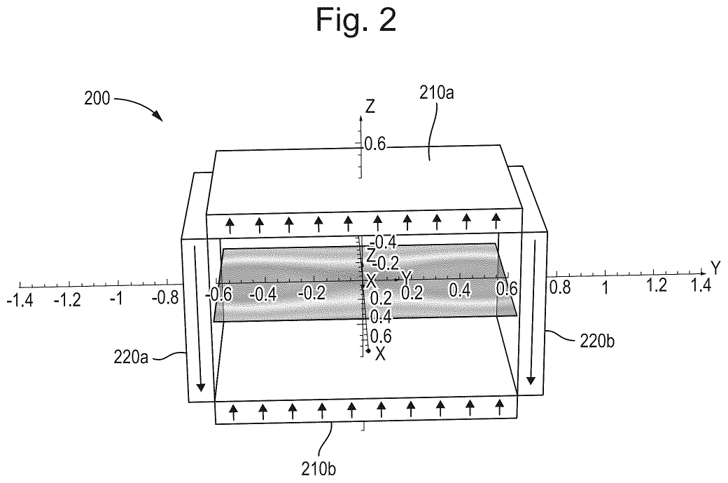

FIG. 2 schematically illustrates a magnet arrangement 200 of an electron trap according to the present invention in a coordinate system (X, Y, Z) having an origin at a centre of the magnet arrangement 200. The magnet arrangement 200 includes a first set of two substantially identical and opposing permanent magnets 210a, 210b which are symmetrically arranged about a Y axis of the coordinate system, and a second set of two substantially identical and opposing permanent magnets 220a, 220b symmetrically arranged about a X axis of the coordinate system.

The two elements 210a, 210b of the first set of magnetic elements may be referred to herein as “top” and “bottom” magnetic elements individually or “primary” magnetic elements collectively, and the two elements 220a, 220b of the second set of magnetic elements may be referred to herein as “left” and “right” magnetic elements individually or “side” or “secondary” magnetic elements collectively. This nomenclature owes to the typical orientation of the magnet arrangement 200 with respect to the axis of the x-ray detector in use when viewed from the perspective of the specimen. This nomenclature also applies more generally to the first and second sets of magnetic elements in other exemplary magnet arrangements described herein.

The magnetic elements 210a, 210b, 220a and 220b are arranged so as to define an interior region therebetween, inside which a magnetic field is generated so as to deflect electrons which enter the interior region away from an x-ray sensor in use. The interior region is partially surrounded by the magnetic elements 210a, 210b, 220a and 220b such that the magnet arrangement 200 has two open ends which are located at two ends of the electron trap respectively. One open end of the magnet arrangement 200 corresponds to a receiving end the electron trap which faces the specimen in use and is the end of the electron trap through which electrons enter the interior region in use. The other open end of the magnet arrangement 200 corresponds to a detector end of the electron trap at an opposite end of the electron trap to the receiving end. The detector end is positioned more proximal to the x-ray detector than the receiving end when in use, and the receiving end is positioned more proximal to the specimen than the detector end when in use.

In this example, each of the magnetic elements 210a, 210b, 220a and 220b in the first and second set of magnetic elements are substantially cuboidal, each element having a substantially planar major surface facing the interior region, a substantially planar major surface distal to the interior region and parallel to the major surface facing the interior region, and four end surfaces. A cross section of each of the magnetic elements 210a, 210b 220a, 220b perpendicular to the longitudinal axis is an oblong (i.e. a non-square rectangle), and a thickness of each element 210a, 210b in the first set of magnetic elements in the Z direction is the substantially the same as the thickness of each element 220a, 220b in the second set of magnetic elements in the Y direction.

In this example the magnetic elements have a thickness of less than 4 mm. In various examples, the magnets may have a thickness of less than 2 mm, and in other examples the magnet thickness is 1 mm.

The magnetic elements 210a, 210b, 220a and 220b are arranged such that the Z axis is normal to the major surface facing the interior region of each element 210a, 210b of the first set of magnetic elements and passes through a centre of the major surface facing the interior region of each element 210a, 210b of the first set of magnetic elements. The Y axis is normal to the major surface facing the interior region of each element 220a, 220b of the second set of magnetic elements and passes through a centre of the major surface facing the interior region of each element 220a, 220b of the second set of magnetic elements. The X axis forms a longitudinal axis which extends through the interior region of the magnet arrangement 200.

The extent of the magnet arrangement 200 in a height direction (the illustrated Z direction) is less than an extent of the magnet arrangement in a width direction (the illustrated Y direction), and the major surfaces of magnetic elements 210a, 210b, 220a and 220b are substantially planar along the X direction in the example of FIG. 2, thereby defining a substantially cuboidal interior region when the magnetic elements 210a, 210b, 220a and 220b are arranged as illustrated in FIG. 2.

A minimum bounding box defined by the extent of the magnet arrangement 200 in the X, Y and Z directions is also substantially cuboidal and has an extent in the height direction less than an extent in the width direction. Accordingly, a projection of the magnet arrangement 200 onto a plane at the receiving end of the electron trap perpendicular to the X direction (referred to herein as an entrance plane) also has an extent in a height direction that is less than an extent in a width direction. In this way, a suitable magnetic field inside the magnet arrangement can be generated to deflect electrons while reducing an extent of the magnet arrangement in a height direction. It follows therefore that an electron trap comprising the magnet arrangement can have a reduced extent in the height direction, thereby allowing an x-ray detector to be positioned closer to the specimen when in use.

In this example, the extent of the trap in the width direction is approximately 40 mm, and in some variations the trap is less than 30 mm wide. Traps of different sizes outside of this are envisaged.

In other non-illustrated examples, each magnetic element is not necessarily substantially planar in the X direction, thus leading to magnet arrangements having varying extents in the height and/or width directions. In these examples, it remains a feature of the magnet arrangements that a projection of the magnet arrangements onto the entrance plane have an extent in a height direction less than an extent in a width direction, thus providing magnet arrangements having a reduced maximum extent in the height direction.

In the example of FIG. 2, the direction of magnetic orientation of each element 210a, 210b of the first set of magnetic elements is the same and is parallel to the height direction (the illustrated Z direction) as illustrated by the arrows provided on the elements 210a, 210b. The direction of magnetic orientation of each element 220a, 220b of the second set of magnetic elements is the same and is opposite to the direction of magnetic orientation of each element 210a, 210b of the first set of magnetic elements. Such a configuration of magnetic orientation directions enables the magnet arrangement to provide a relatively strong field within the interior region, and a relatively weak field outside of the interior region. In general, it is advantageous to provide a magnetic field which is orthogonal or substantially orthogonal to the trajectory of a majority of the incoming electrons.

An illustration of a Z component of the magnetic field (B-field) generated by the magnet arrangement 200 in a vacuum in a plane perpendicular to the Z axis at the centre of the interior region is provided by the heat map plot depicted in FIG. 2. The heat map illustrates that compared to a conventional 2-bar magnet arrangement in which the magnetic field is strongest at the centre of the region between the magnets, the magnetic field is enhanced in portions of the interior region away from the centre of the arrangement and more proximate to each of the side magnetic elements 220a, 220b. The magnetic field within the interior region proximal to the side magnetic elements 220a, 220b has the same direction as the direction of magnetic orientation of the top and bottom elements 210a, 210b.

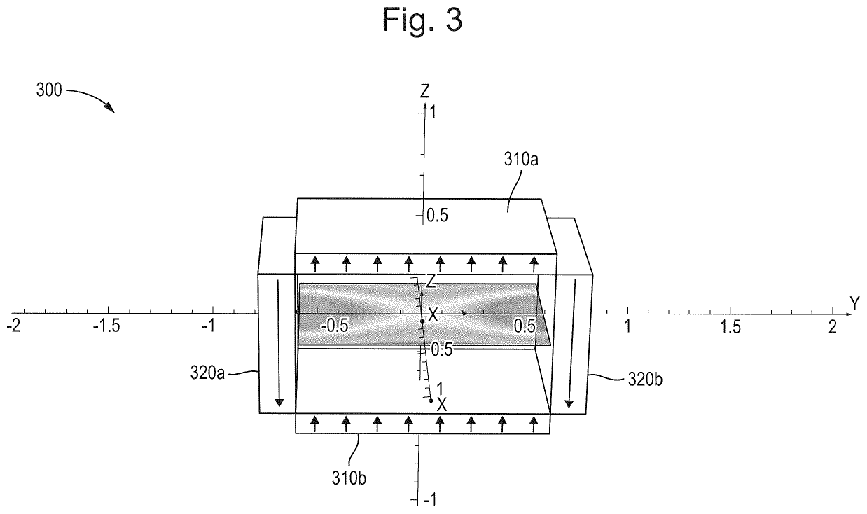

FIG. 3 illustrates a similar magnet arrangement 300 to that illustrated in FIG. 2, differing in that each element 320a, 320b of the second set of magnetic elements is provided with the same volume as each element 310a, 310b of the first set of magnetic elements, resulting in the side magnets being of equal strength as the primary magnets. Since each element 310a, 310b of the first set of magnetic elements has an extent in the Y direction greater than the extent of each element 320a, 320b of the second set of magnetic elements in the Z direction, each magnetic element 320a, 320b of the second set of magnetic elements is provided with a thickness (typically an average thickness) in the Y direction which is greater than a thickness (typically an average thickness) of each element 310a, 310b of the first set of magnetic elements in the Z direction so as to result in the same volume.

In all examples of the invention, additional thickness to the side magnetic elements may be obtained either through providing thicker monolithic magnetic elements, or by providing one or more further sets of two magnetic elements, where each additional element is arranged adjacent to the major surface distal to the interior region of each element of the side elements respectively. These further sets of magnetic elements will typically have the same direction of magnetic orientation as the side elements.

The heat map of FIG. 3, showing an equivalent component of a magnetic field as illustrated in FIG. 2, illustrates that increasing the volume and thus magnetic energy of the side elements 320a, 320b further concentrates the magnetic field in portions of the interior region away from the centre of the arrangement and proximal to each of the side magnetic elements 320a, 320b.

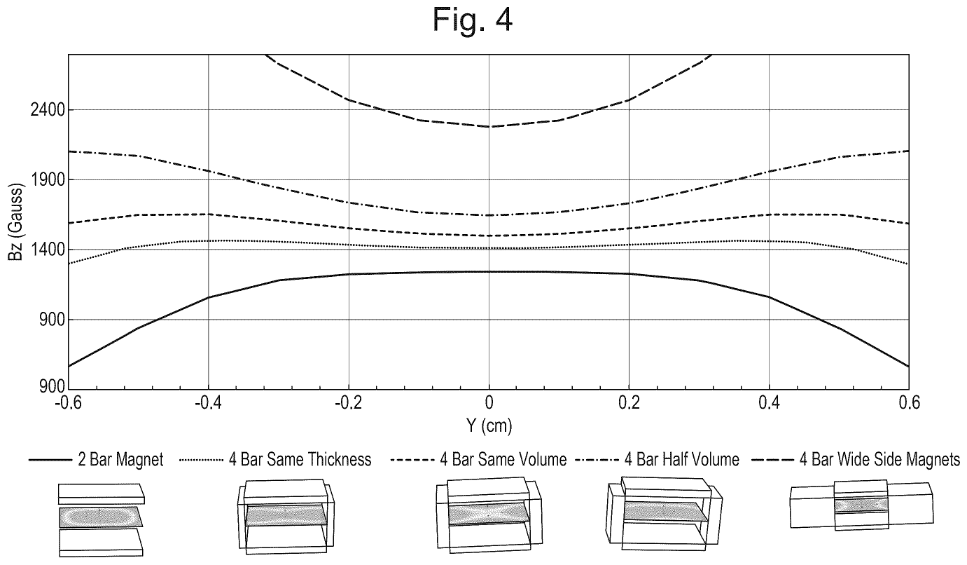

FIG. 4 illustrates how the strength of the magnetic field varies across the width direction. The graph shows a magnitude of the Z component of the magnetic field in a plane perpendicular to the Z axis along Y axis (X=0, Z=0) for different magnet arrangements. The magnet arrangements associated with the plot are the magnet arrangement 200 of FIG. 2 (labelled as “4 Bar Same Thickness”), the magnet arrangement 300 of FIG. 3 (labelled as “4 bar same volume”), a magnet arrangement similar to that in FIGS. 2 and 3 where each element of the first set of magnetic elements is provided with half the volume of each element of the second set of magnetic elements (labelled as “4 Bar Half Volume”), a magnet arrangement similar to that in FIGS. 2 and 3 where the volume of each element of the second set of magnetic elements is significantly larger than a volume of each element of the first set of magnetic elements (labelled as “4 Bar Wide Side Magnets”), and a comparative example of a 2-bar magnet arrangement (labelled as “2 Bar Magnet”).

The graph of FIG. 4 illustrates that, in general, as the volume of each element of the second set of magnetic elements (the side magnetic elements) is increased compared to the volume of each element of the first set of magnetic elements (the top and bottom elements), or indeed the combined volume of the second set of magnetic elements is increased compared to the combined volume of the first set of magnetic elements, the stronger the magnetic field that is provided at the sides of the interior region proximal to each of the side magnetic elements. Such an effect is not a direct result of the volumes of the magnetic elements, but the increased magnetic strength provided by magnetic elements of increased volume. Indeed, a similar effect may be observed by increasing a magnetic strength of the side magnetic elements with respect to the top and bottom magnetic elements in a different manner, for example by utilising different magnetic materials or different fields/processes to magnetize the magnetic elements. In each of the different magnet arrangements according to the invention, the Z component of the B-field has a flux density of greater than 1,000 Gauss at all positions along the Y axis within the interior region.

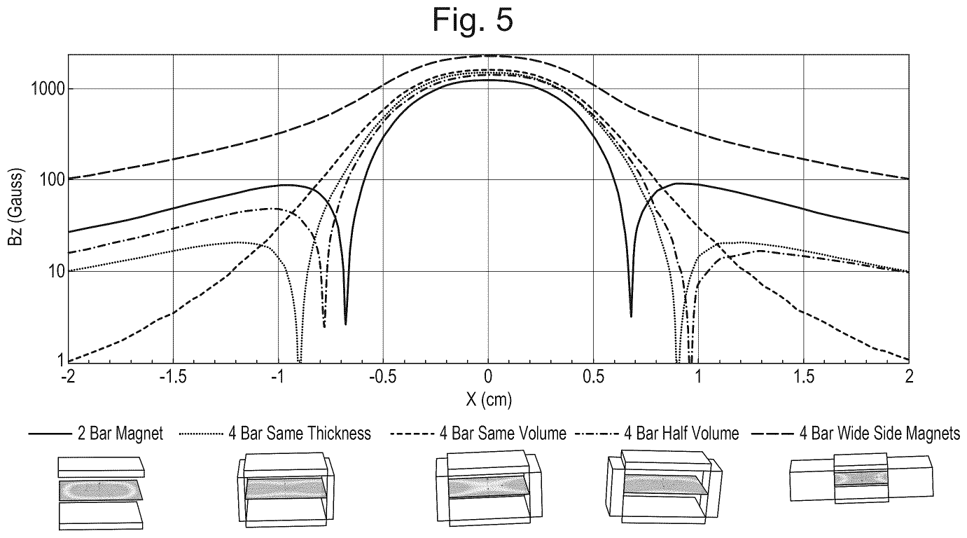

FIG. 5 is a graph that illustrates how the component of the magnetic field discussed FIG. 4 (this time shown on a logarithmic scale) varies along the X axis (Y=0, Z=0). The magnet arrangements associated with the graph of FIG. 5 are the same as those discussed in relation to FIG. 4. For all arrangements, the Z component of the magnetic field is strongest at X=0 and is reduced away from this point. For magnet arrangements where the side magnetic elements are smaller than the top and bottom magnetic elements, the magnetic field changes direction as illustrated by the turning points on the plot of absolute Z component of the magnetic field. Of the magnet arrangements illustrated, the Z component of the magnetic field in the magnet arrangement illustrated in FIG. 3 converges most rapidly to zero with increasing distance along the X axis from X=0, thereby providing a geometry suited to reducing stray magnetic fields outside of the interior region.

It has also been realised by the inventors that the direction and strength of the magnetic field generated both inside and outside of the interior region of a magnet arrangement is affected by how end surfaces of the elements of the magnet arrangement are arranged relative to one another, particularly when located inside of a shielded housing made of a material of high magnetic permeability.

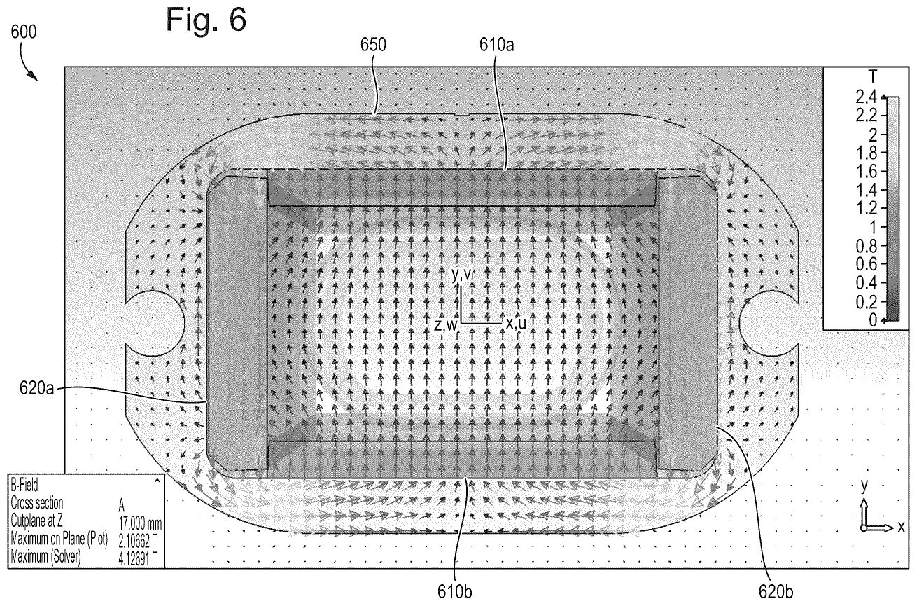

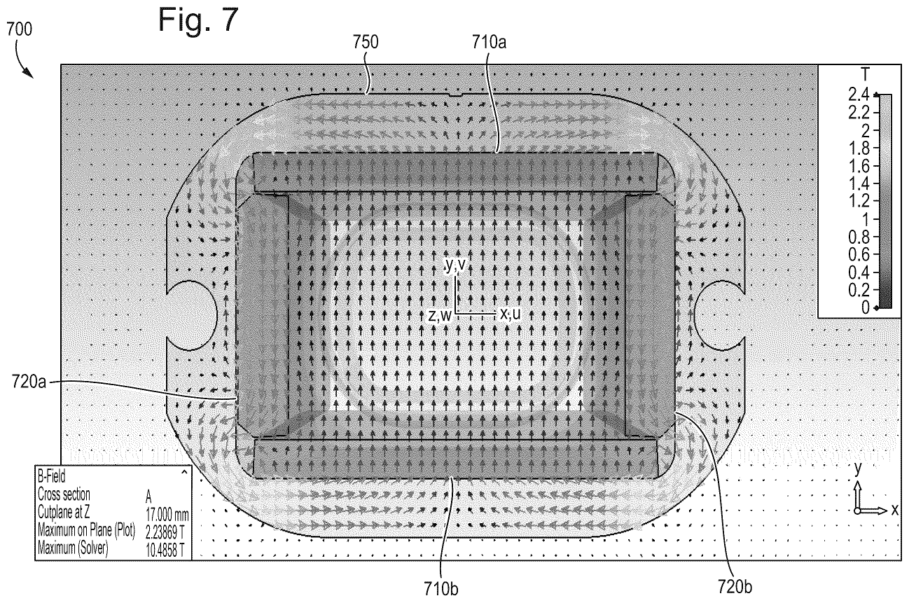

FIGS. 6 and 7 schematically illustrate magnet arrangements 600, 700 of an electron trap according to the present invention in a coordinate system (u, v, w) having an origin at a centre of the magnet arrangements 600 and 700 respectively. The u axis corresponds to the horizontal direction on the page, the v axis corresponds to the vertical direction on the page, and the w axis corresponds to the direction into and out of the page.

As with the previous examples, the magnet arrangements illustrated in FIGS. 6 and 7 include a first set of two opposing magnetic elements 610a, 610b, 710a, 710b and a second set of two opposing magnetic elements 620a, 620b, 710a, 710b defining an interior region similar to the elements with like reference signs shown in FIGS. 2 and 3.

The examples illustrated in FIGS. 6 and 7 differ from those described previously in that they further comprise a shielded housing 650, 750 made of a material of high permeability (e.g. a soft magnetic material) which surrounds the outer surfaces of the magnetic elements 610a, 610b, 620a, 620b and the magnetic elements 710a, 710b, 720a, 720b respectively. Furthermore, the magnetic elements in the examples illustrated in FIGS. 6 and 7 are arranged such that the shape of the interior region is a truncated pyramid, tapering towards the entrance or receiving end of the trap and widening towards the detector end.

In FIG. 6, the magnetic elements 610a, 610b, 620a, 620b are arranged such that a separation distance between each element 610a, 610b of the first set of magnetic elements in the v direction is less than an extent of each element 620a, 620b of the second set of magnetic elements in the v direction, and such that the major surfaces facing the interior region of each element 620a, 620b of the second set of magnetic elements overlap with each element 610a, 610b of the first set of magnetic elements. In the illustrated example, poles of the side magnetic elements 620a, 620b abut against the housing 650, and opposing end surfaces of the top and bottom elements 610a, 610b abut against respective major surfaces facing the interior region of the side elements 620a, 620b.

In FIG. 7, the magnetic elements 710a, 710b, 720a, 720b are arranged such that a separation distance between each element 710a, 710b of first set of magnetic elements in the v direction is greater than an extent of each element 720a, 720b of the second set of magnetic elements in the v direction such that the major surfaces facing the interior region of each element 710a, 710b of the first set of magnetic elements overlap with each element 720a, 720b of the second set of magnetic elements. In the illustrated example, poles of the side magnetic elements 720a, 720b abut against respective major surfaces facing the interior region of the top and bottom elements 710a, 710b, and opposing end surfaces of the elements 710a, 710b abut against the housing 750.

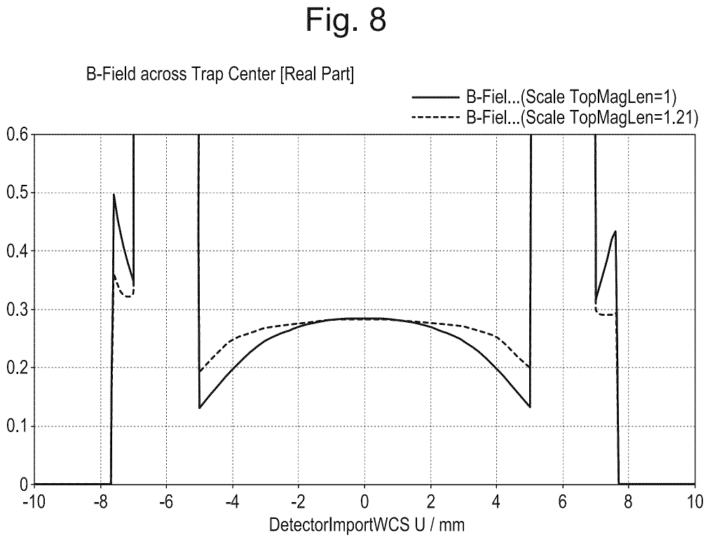

As shown by the simulated magnetic field lines illustrated in FIGS. 6 and 7, the way in which the magnetic elements abut against each other and/or abut against the housing results in a differing magnetic field both inside and outside of the interior region. FIG. 8 is a graph illustrating the magnitude of the B-field in Tesla at different distances from the centre of the interior region along the u axis (v=0, w=0). The magnitude in Tesla of the B-field of the two arrangements illustrated in FIGS. 6 and 7 is substantially the same at u=0, but as the location on the u axis tends towards the points of intersection with the major surfaces facing the interior region of each element 620a, 620b and 720a, 720b respectively (shown as the discontinuities at u≈−5 mm and u ≈5 mm where the magnetic field changes direction), the magnitude of the B-field diverges between the magnet arrangements illustrated in FIGS. 6 and 7, with the magnitude of the B-field generated by the arrangement of FIG. 7 being greater than that of the arrangement of FIG. 6. At the intersection points, the magnitude of the B-field associated with the magnet arrangement of FIG. 7 is increased by approximately 40% compared to the magnitude of the B-field associated with the magnet arrangement of FIG. 6.

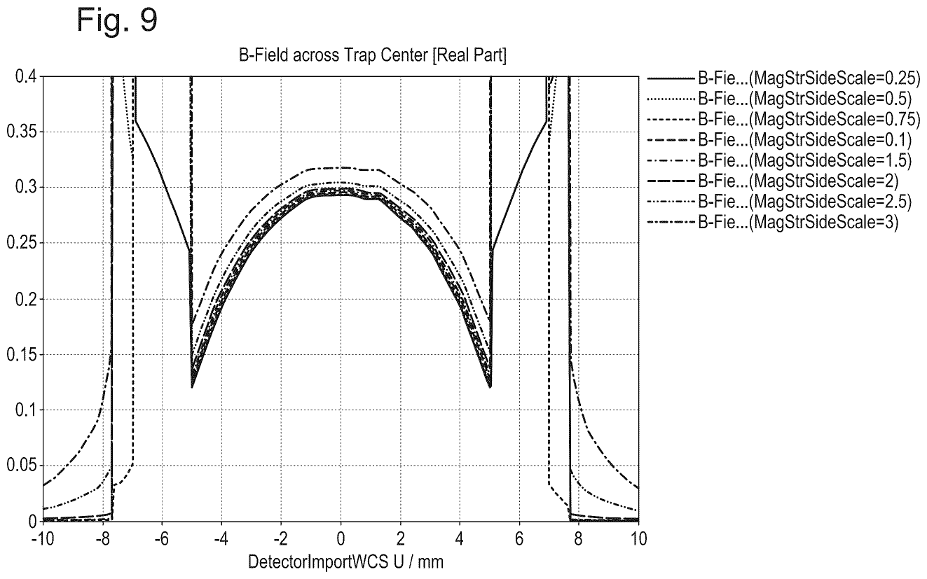

FIG. 9 is a graph which illustrates the effect of changing the magnetic energy of the side magnets 620a, 620b in the magnet arrangement of FIG. 6 on the magnitude of the B-field along the u axis (v=0, w=0). The legend of the graph shows a plurality of numbers labelled “MagStrSideScale” representing the ratio of the magnetic energy of the side magnets 620a, 620b to the magnetic energy of the top and bottom magnets 610a, 610b. A multiplier of 1 indicates that the magnetic energy of each of the side magnets 620a, 620b is equal to the magnetic energy of each of the top and bottom magnets 610a, 610b. The graph illustrates that changing the ratio has little impact of the magnitude of the B-field within the trap up until the housing saturates, from which point any field not contained by the housing “spills out” and illustrates behaviour resembling magnets in air.

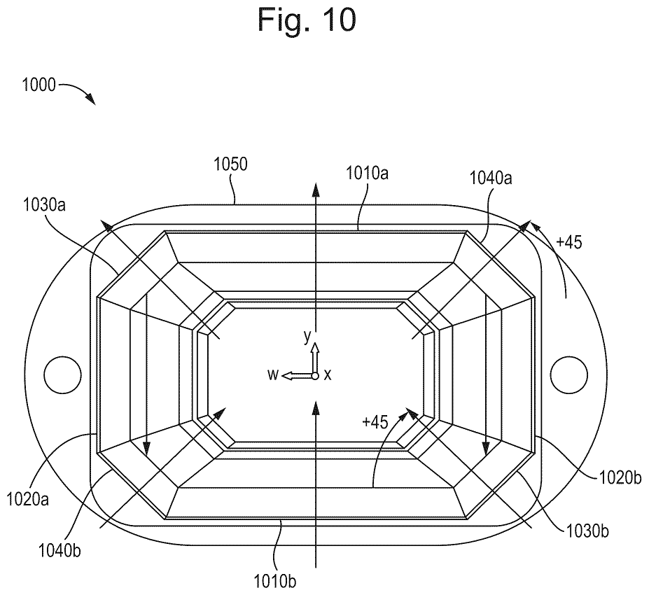

FIG. 10 schematically illustrates a magnet arrangement 1000 of an electron trap according to the present invention viewed from a detector end of the magnetic electron trap (i.e. from the perspective of the detection element of the x-ray detector in use). The illustration is provided in a coordinate system (w, v, u) having an origin at a centre of the magnet arrangement 1000. The w axis corresponds to the horizontal direction on the page, the v axis corresponds to the vertical direction on the page, and the u direction corresponds to the direction into and out of the page.

The magnet arrangement 1000 includes a first set of two opposing permanent magnets 1010a, 1010b symmetrically arranged about a w axis of the coordinate system, a second set of two opposing permanent magnets 1020a, 1020b symmetrically arranged about a v axis of the coordinate system, a third set of two opposing permanent magnets 1030a, 1030b and a fourth set of two opposing permanent magnets 1040a, 1040b.

The two elements 1030a, 1030b of the third set of magnetic elements and the two elements 1040a, 1040b of the fourth set of magnetic elements may be referred to herein as “corner” magnetic elements collectively.

The magnetic elements 1010a, 1010b, 1020a, 1020b, 1030a, 1030b, 1040a, 1040b are arranged so as to define an interior region therebetween, inside which a magnetic field is generated so as to deflect electrons which enter the interior region away from an x-ray sensor in use. In a similar manner to the examples described previously, the interior region is partially surrounded by the magnetic elements 1010a, 1010b, 1020a, 1020b, 1030a, 1030b, 1040a, 1040b such that the magnet arrangement 1000 has two open ends which are located at two ends of the electron trap respectively. One open end of the magnet arrangement 1000 corresponds to a receiving end the electron trap which faces the specimen in use and is the end of the electron trap through which electrons enter the interior region in use. The other open end of the magnet arrangement 1000 corresponds to a detector end of the electron trap at an opposite end of the electron trap to the receiving end. The detector end is positioned more proximate to the x-ray detector than the receiving end when in use, and the receiving end is positioned more proximate to the specimen than the detector end when in use.

Each of the magnetic elements 1010a, 1010b, 1020a, 1020b, 1030a, 1030b, 1040a, 1040b are shaped in the illustrated example as trapezoidal prisms, each element having a substantially planar major surface facing the interior region, a substantially planar major surface distal to the interior region and parallel to the major surface facing the interior region, and four minor end surfaces. A cross section of each of the magnetic elements 1010a, 1010b, 1020a, 1020b, 1030a, 1030b, 1040a, 1040b perpendicular to the longitudinal axis (the u axis in FIG. 10) is an isosceles trapezium, and a thickness of each element 1010a, 1010b, 1020a, 1020b, 1030a, 1030b, 1040a, 1040b in a direction normal to the major surfaces of each element is substantially the same.

The magnetic elements 1010a, 1010b, 1020a, 1020b, 1030a, 1030b, 1040a, 1040b are arranged in a non-circular ring defining an interior region such that the u axis forms a longitudinal axis which extends through the interior region of the magnet arrangement 1000. In the direction into the page along the longitudinal axis (i.e. along the u axis) between the detector end of the electron trap and the receiving end of the electron trap, a cross-sectional area of the interior region and a correspondingly a cross-sectional area of the magnet arrangement decreases, thereby providing an interior region that resembles a truncated pyramid with a polygonal irregular octagon for a base.

The corner magnetic elements 1030a, 1030b, 1040a, 1040b are each arranged between an element 1010a, 1010b of the first set of magnetic elements and an element 1020a, 1020b of the second set of magnetic elements. Specifically, each element of the third set of magnetic elements and fourth set of magnetic elements is arranged between an end surface of an element 1010a, 1010b of the first set of magnetic elements and an end surface of an element 1020a, 1020b of the second set of magnetic elements. The end surfaces of the magnetic elements 1010a, 1010b, 1020a, 1020b, 1030a, 1030b, 1040a, 1040b abut against one another in order to provide a continuous non-circular ring, the inside of which defining the interior region which electrons enter in use. In the example of FIG. 10, adjacent ones of the non-parallel end surfaces of each magnetic element 1010a, 1010b, 1020a, 1020b, 1030a, 1030b, 1040a adjoin so as to define the interior region. The interior region has an extent in a height direction (the illustrated v direction) that is less than an extent in a width direction (the illustrated w direction).

The magnet arrangement 1000 further comprises a shielded housing 1050 made of a material of high permeability which surrounds the outer surfaces of the magnetic elements 1010a, 1010b, 1020a, 1020b, 1030a, 1030b, 1040a, 1040b. Since each of the magnetic elements are planar along the longitudinal axis and have a thickness in a direction normal to the major surfaces of each element which substantially the same, this enables the overall geometry of the magnet arrangement 1000 including the housing 1050 to have an extent in the height direction that is less than an extend in the width direction.

A minimum bounding box defined by the extent of the magnet arrangement 1000 in the w, v and u directions is substantially cuboidal and has an extent in the height direction less than an extent in the width direction. Accordingly, a projection of the magnet arrangement 1000 onto a plane at the receiving end of the electron trap perpendicular to the u direction (referred to herein as an entrance plane) also has an extent in a height direction that is less than an extent in a width direction. In this way, a suitable magnetic field inside the magnet arrangement can be generated to deflect electrons while reducing an extent of the magnet arrangement in a height direction. It follows therefore that an electron trap comprising the magnet arrangement can have a reduced extent in the height direction, thereby allowing an x-ray detector to be positioned closer to the specimen when in use. Compared to a magnet arrangement with two sets of two magnetic elements, the additional space provided between the magnet arrangement 1000 and the cuboidal minimum bounding box owing to the corner magnetic elements, namely space adjacent to major surfaces distal to the interior region of each element of the third set of magnetic elements and fourth set of magnetic elements, may be provided with ferromagnetic material.

In other non-illustrated examples having four sets of two magnetic elements such as that shown in FIG. 10, each magnetic element may not be substantially planar. In these examples, it remains a feature of the magnet arrangements that a projection of the magnet arrangements onto the entrance plane have an extent in a height direction less than an extent in a width direction, thus providing magnet arrangements having a reduced maximum extent in the height direction.

The projected direction (i.e. the projection of the direction onto the entrance plane) of magnetic orientation of each element 1010a, 1010b of the first set of magnetic elements is the same (referred to hereafter as a projected first direction of magnetic orientation) and is parallel to the height direction as illustrated by the arrows which intersect the elements 1010a, 1010b. The projected direction of magnetic orientation of each element 1020a, 1020b of the second set of magnetic elements is the same (referred to hereafter as a projected second direction of magnetic orientation) and is opposite to the projected direction of magnetic orientation of each element 1010a, 1010b of the first set of magnetic elements.

Each element 1030a, 1030b of the third set of magnetic elements has a direction of magnetic orientation, and a vector sum of the directions of magnetic orientation of the third set of magnetic elements is a third resultant direction of magnetic orientation. Each element 1040 of the fourth set of magnetic elements has a direction of magnetic orientation, and a vector sum of the directions of magnetic orientation of the fourth set of magnetic elements is a fourth resultant direction of magnetic orientation, wherein the third resultant direction of magnetic orientation and the fourth resultant direction of magnetic orientation are orthogonal.

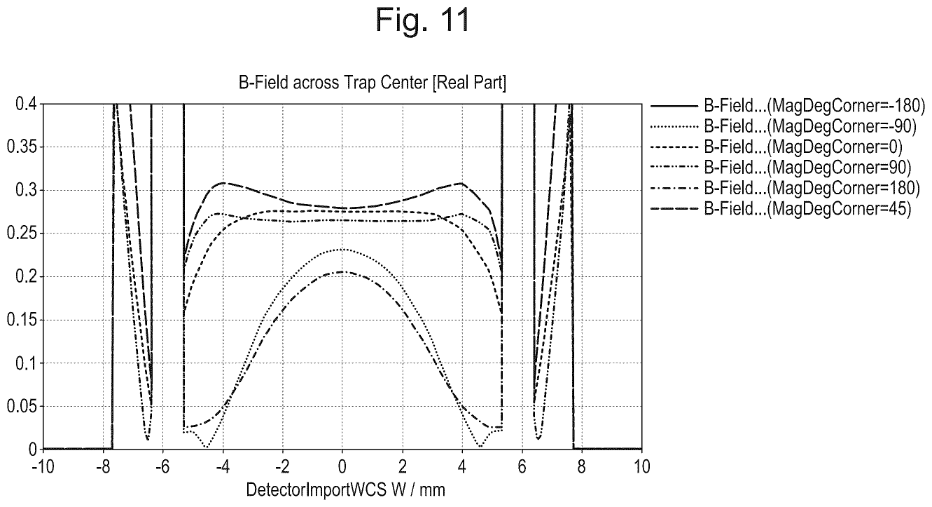

In the example of FIG. 10, projections of the magnetic orientations of each magnetic element in the third set of magnetic elements and fourth set of magnetic elements onto the entrance plane each form an angle of 45 degrees to the height direction, and correspondingly 45 degrees to the width direction. However, projections of the magnetic orientations of the elements of the third set and fourth set of magnetic elements onto the entrance plane may form different angles, and the effect of these different angles on the generated magnetic field is illustrated in the graph of FIG. 11.

FIG. 11 is a graph illustrating the magnitude of the B-field at different distances from the centre of the interior region in the w direction, measured at v=0 and u=0, where the different lines correspond to different angles of projection of the magnetic orientations of each magnetic element in the third set of magnetic elements and fourth set of magnetic elements onto the entrance plane. The legend of the graph recites angles “MagDegCorner”, defined in that at 90 degrees, projections of the magnetic orientations of each magnetic element in the third set of magnetic elements and fourth set of magnetic elements are aligned with the projections of the magnetic orientations of each magnetic element in the first set of magnetic elements, while at −90 degrees, projections of the magnetic orientations of each magnetic element in the third set of magnetic elements and fourth set of magnetic elements are aligned with the projections of the magnetic orientations of each magnetic element in the second set of magnetic elements.

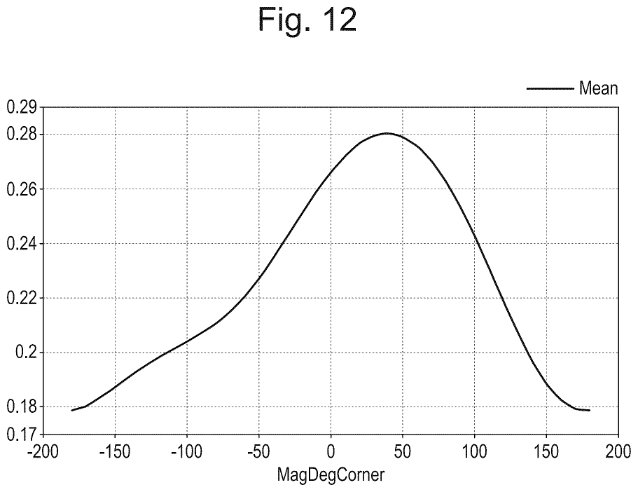

FIG. 12 is a graph illustrating average magnitude of the B-field within the interior region for different magnetization orientations of the corner magnets 1030a, 1030b, 1040a, 1040b in the magnet arrangement of FIG. 10.

FIGS. 11 and 12 illustrate that the largest magnitude of the B-field inside the interior region and the highest average magnitude of the B-field within the interior region is obtained when the corner elements have a direction of magnetic orientation such that their projections onto the entrance plane form an angle of 45 degrees to the height and width directions (corresponding to the arrangement shown in FIG. 10). However, other orientations may still provide a suitably strong B-field within the interior region so as to deflect electrons away from an x-ray detector in use. The corner elements may, for example, have directions of magnetic orientation such that their projections onto the entrance plane form non-zero angles to the width direction, preferably between 30 and 60 degrees to the width direction, and more preferably between 40 and 50 degrees to the width direction.

Furthermore, it has been observed by the inventors based on this graph that how the side and primary magnets are arranged so as to form the interior region (in the example of FIG. 10 through corner magnets) has a greater effect on the resultant magnetic field than the absolute strength of the side magnets. It has also been observed that the magnetization orientation of the corner magnets creates changes in the magnitude of the B-field which are at least of similar order than changing the strength of the side magnets from 0 to 2 times the strength of the top/bottom magnets.

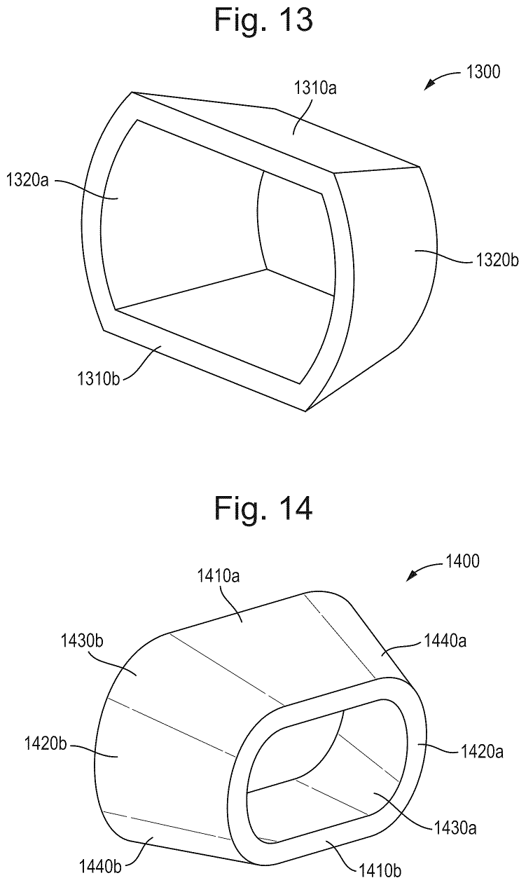

FIG. 13 illustrates a magnet arrangement 1300 of a sixth exemplary electron trap according to the present invention in a perspective view from a detector side of the magnetic electron trap. The arrangement differs from earlier described examples in that it includes coaxial tapered cylindrical side magnets 1320a, 1320b, together with trapezoidal magnets top 1310a and bottom 1310b that are similar to the first set of magnet elements of those previous examples. For simplicity, joins between adjacent magnet elements are not shown in FIG. 13 or in FIG. 14. However, in the present example, variations are envisaged in which the second set of magnet elements, that is the side elements, are formed from a pair of exactly two magnetic elements, analogously to the first described example. More preferably, each element 1320a, 1320b of the second set of elements is provided as a plurality of sub-elements. More preferably, each of the curved sections 1320a, 1320b, and more preferably still each of the trapezoidal sections 1320a, 1310b also, is provided as two or more sub-elements. Each sub-element of an element is preferably provided with a different magnetisation orientation.

The use of cylindrical or conical magnets may provide advantages compared with arrangements that use exclusively trapezoidal magnets. Cylindrical or conical magnet geometries may advantageously be produced using existing manufacturing techniques such as axial grinding. Moreover, compared with the fifth example arrangement, for instance, the present example may permit a more efficient use of space, which allows for the inclusion of more magnetic material and/or shielding material. This results in stronger field strength and less field leakage, enhancing the overall performance of the electron trap. On the other hand, manufacture of configurations such as the present example is typically more complex than that of preceding examples, owing to the processes required to achieve the desired shape and magnetization orientation for instance.

The arrangement may be manufactured using various methods, including cutting the magnetic elements 1320a, 1320b roughly from blocks of stock magnetic material, securing the elements together, with an adhesive for example, and subsequently performing cylindrical or conical turning and grinding to achieve the required accuracy of shape and size. The term “magnetic material” as used in relation to this production step may refer generally to a material capable of being magnetized. That is, it may refer to a ferromagnetic material or a material comprising magnetic domains that can be aligned in a preferred direction.

The magnetic elements are typically cut, shaped, ground, or otherwise mechanically processed from the stock material. Where these machining operations are performed on material in an unmagnetized state, several problems associated with processing magnetized components, including the risk of partial demagnetization during machining as well as unwanted magnetic interactions during fabrication, may be avoided.

Once all mechanical processing is complete, each individual magnetic element may be magnetized in a controlled external magnetic field, aligning the domains and imparting the desired magnetization direction for the intended magnet arrangement. This fabrication process is described in the context of the example shown in FIG. 13 but may also be applicable to any of the examples described herein. Following this process, the elements would be separated again for use only in the side segments, with the top and bottom flat segments 1310a, 1310b being made separately and added to produce the depicted arrangement.

FIG. 14 shows a magnet arrangement 1400 of a sixth exemplary electron trap, which employs curved magnetic elements similarly to the preceding example. In particular, the arrangement 1400 includes a third set 1430a, 1430b and a fourth set 1440a, 1440b of magnet elements, analogous to the octagonal arrangements described earlier in this disclosure. However, in the present configuration, the side and corner magnets, i.e., the second, third, and fourth sets, are rounded.

The lines depicted between the magnet elements also correspond to tangent edges between adjoining curved faces. In other words, in the present example, the magnet arrangement is segmented at lines representing discontinuities in surface geometry. However, in some envisaged variations in which the arrangement has the same shape as that depicted, the arrangement may be divided into elements or sub-elements, that is, separate magnet pieces, along different lines. For example, in some variations of the arrangement in FIG. 14, the curved portions may each be formed from one or more elements or sub-elements.

The example of FIG. 14 is similar to that of FIG. 13 in that it is formed from flat top and bottom sections and curved side sections, and both flat and curved sections could be made of two or more sub-elements in various implementations. FIGS. 13 and 14 differ in that the curved elements in FIG. 13 are suited to being shaped by turning or grinding, as they are formed as segments of a conical cylinder. The curved sections in FIG. 14, conversely, are typically produced by spark erosion, owing to their more complex shape. The curved sections in FIG. 14 could similarly be made of sub-elements as the sections in FIG. 13, which might not necessarily be on the tangent edges shown.

An advantage of this configuration is that the internal aperture profile, that is the shape of the interior region as defined by the inward-facing magnet surfaces, may conform more accurately to the collection solid angle, thereby maximizing the magnet and shielding material for maximum field strength and minimum leakage. This precise alignment enhances the overall performance of the electron trap by concentrating the magnetic field such that the internal field strength is enhanced where it is most needed, reducing stray (external) fields, and improving the efficiency of electron deflection.

The manufacturing process is typically more complex than that of trapezoidal magnets, usually requiring wire electrical discharge machining (EDM) to achieve the desired shapes and magnetization orientations. Nevertheless, the arrangement 1400 may be manufactured using any of a number of methods, including cutting the magnetic elements and joining the cut pieces together, followed by a final cut of the shape using wire eroding or similar methods to create the depicted form.

1. An electron trap for use in a system for performing x-ray analysis of a specimen, comprising:
a magnet arrangement comprising a first set of two opposing magnetic elements and a second set of two opposing magnetic elements, the magnetic elements arranged so as to define an interior region therebetween such that when in use, electrons travelling from the specimen and received by the electron trap enter the interior region through an entrance plane at a receiving end of the electron trap, the entrance plane being perpendicular to a longitudinal axis of the magnet arrangement;
wherein an extent of a projection of the magnet arrangement onto the entrance plane in a height direction is less than an extent of the projection of the magnet arrangement onto the entrance plane in a width direction.

2. The electron trap according to claim 1, wherein each of the magnetic elements has a respective direction of magnetic orientation, and a vector sum of the directions of magnetic orientation of the first set of magnetic elements has an opposite direction to that of a vector sum of the directions of magnetic orientation of the second set of magnetic elements, preferably wherein a projection onto the entrance plane of the vector sum of the directions of magnetic orientation of the first set of magnetic elements is parallel to the height direction.

3. The electron trap according to claim 2, wherein each element of the first set of magnetic elements has a direction of magnetic orientation, wherein a vector sum of the directions of magnetic orientation of the first set of magnetic elements is a first resultant direction of magnetic orientation, and each element of the second set of magnetic elements has a direction of magnetic orientation, wherein a vector sum of the directions of magnetic orientation of the second set of magnetic elements is a second resultant direction of magnetic orientation, wherein the first resultant direction of magnetic orientation and the second resultant direction of magnetic orientation are opposite, preferably wherein a projection onto the entrance plane of the first resultant direction of magnetic orientation is parallel to the height direction.

4. The electron trap according to claim 1, wherein each element of the first set of magnetic elements and second set of magnetic elements comprises a planar major surface facing the interior region, wherein the magnetic elements are arranged such that a projection onto the entrance plane of a normal vector of the major surface facing the interior region of each element of the first set of magnetic elements is collinear with a first direction, and a projection onto the entrance plane of a normal vector of the major surface facing the interior region of each element of the second set of magnetic elements is collinear with a second direction, wherein the first direction and second direction are orthogonal.

5. The electron trap according to claim 1, wherein each element of the second set of magnetic elements comprises a curved major surface facing the interior region.

6. The electron trap according to claim 1, wherein each element of the first set of magnetic elements abuts against each element of second set of magnetic elements, wherein:
a separation distance between each element of the first set of magnetic elements in the height direction is less than an extent of each element of the second set of magnetic elements in the height direction such that the major surfaces facing the interior region of each element of the second set of magnetic elements overlap with each element of the first set of magnetic element; or
a separation distance between each element of first set of magnetic elements in the height direction is greater than an extent of each element of the second set of magnetic elements in the height direction such that the major surfaces facing the interior region of each element of the first set of magnetic elements overlap with each element of the second set of magnetic elements.

7. The electron trap according to claim 1, wherein the magnet arrangement further comprises a third set of two opposing magnetic elements and a fourth set of two opposing magnetic elements arranged so as to further define the interior region therebetween, each element of the third set of magnetic elements and fourth set of magnetic elements being arranged between an element of the first set of magnetic elements and an element of the second set of magnetic elements.

8. The electron trap according to claim 7, wherein each element of the third set of magnetic elements and fourth set of magnetic elements is arranged between an end surface of an element of the first set of magnetic elements and an end surface of an element of the second set of magnetic elements.

9. The electron trap according to claim 7, wherein each element of the third set of magnetic elements and fourth set of magnetic elements abuts against an end surface of an element of the first set of magnetic elements and an end surface of an element of the second set of magnetic elements.

10. The electron trap according to claim 7, wherein each element of the third set of magnetic elements has a direction of magnetic orientation, wherein a vector sum of the directions of magnetic orientation of the third set of magnetic elements is a third resultant direction of magnetic orientation, and each element of the fourth set of magnetic elements has a direction of magnetic orientation, wherein a vector sum of the directions of magnetic orientation of the fourth set of magnetic elements is a fourth resultant direction of magnetic orientation, wherein the third resultant direction of magnetic orientation and the fourth resultant direction of magnetic orientation are orthogonal.

11. The electron trap according to claim 7, wherein each element of the third set of magnetic elements has a direction of magnetic orientation, wherein a vector sum of the directions of magnetic orientation of the third set of magnetic elements is a third resultant direction of magnetic orientation, and each element of the fourth set of magnetic elements has a direction of magnetic orientation, wherein a vector sum of the directions of magnetic orientation of the fourth set of magnetic elements is a fourth resultant direction of magnetic orientation, wherein a projection onto the entrance plane of the first resultant direction of magnetic orientation is parallel to the height direction, and projections of the third resultant direction of magnetic orientation and fourth resultant direction of magnetic orientation onto the entrance plane each form a non-zero angle to the width direction, wherein projections of the third resultant direction of magnetic orientation and fourth resultant direction of magnetic orientation onto the entrance plane each form an angle with the width direction in the range 5-85 degrees.

12. The electron trap according to claim 7, wherein ferromagnetic material is disposed adjacent to major surfaces distal to the interior region of each element of the third set of magnetic elements and fourth set of magnetic elements.

13. The electron trap according to claim 1, further comprising a fifth set of two magnetic elements, wherein each element of the fifth set of magnetic elements is arranged adjacent to a major surface distal to the interior region of each element of the second set of magnetic elements respectively, wherein each element of the fifth set of magnetic elements has a direction of magnetic orientation parallel to a direction of magnetic orientation of an adjacent element of the second set of magnetic elements.

14. The electron trap according to claim 1, wherein an average thickness of each element of the first set of magnetic elements is less than an average thickness of each element of the second set of magnetic elements.

15. The electron trap according to claim 1, wherein the magnetic elements are made from a permanent magnetic material, wherein a magnetic energy of each element of the first set of magnetic elements is greater than or equal to a magnetic energy of each element of the second set of magnetic elements.

16. The electron trap according to claim 1, having less than or equal to 20 magnetic elements.

17. An x-ray detector, comprising:
a detection element; and
an electron trap according to claim 1.

18. The x-ray detector according to claim 17, wherein the detection element is one of a silicon drift detector, a PIN diode detector, a gas proportional counter, a CCD array, and a CMOS array.

19. The x-ray detector according to claim 17, wherein the detection element has an extent in the height direction less than an extent in the width direction.

20. An apparatus for analysing a specimen, the apparatus comprising:
an electron beam assembly for generating a focused electron beam comprising a polepiece; and
an x-ray detector according to claim 17.
